(19) United States
(12) Patent Application Publication
(10) Pub. No.: US 2026/0033056 A1
(43) Pub. Date: Jan. 29, 2026

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Binyan WANG, Beijing (CN); Cong LIU, Beijing (CN); Gukhwan SONG, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/996,839

(22) PCT Filed: Apr. 17, 2024
(86) PCT No.: PCT/CN2024/088183

§ 371 Date: Jan. 17, 2025

(30) Foreign Application Priority Data
May 8, 2023 (CN) 202310511070.2

(51) Int. Cl. H10H 29/32; H10D 86/40; H10D 86/60; H10H 29/49; H10H 29/855

(52) U.S. Cl. CPC H10H 29/32; H10D 86/441; H10D 86/481; H10D 86/60; H10H 29/49; H10H 29/8552

(57) ABSTRACT

A display substrate and a display device are provided. In the display substrate, a first target scanning line is coupled to each target virtual sub-pixel drive circuit and each first target sub-pixel drive circuit in a corresponding target drive circuit row, respectively; an orthographic projection of the conductive connection line on a base substrate overlaps at least partially with an orthographic projection of the first target scanning line on the base substrate; and a gate of a drive transistor in at least a portion of the sub-pixel drive circuits included in the target drive circuit row is configured to have substantially the same potential as a gate of a drive transistor in at least a portion of the sub-pixel drive circuits included in a non-target drive circuit row after charging.

### CROSS REFERENCE OF RELATED APPLICATION

The present disclosure claims a priority of Chinese patent disclosure No. 202310511070.2 filed on May 8, 2023, which is incorporated herein by reference in its entirety.

### TECHNICAL FIELD

The present disclosure relates to the field of display technology, and in particular to a display substrate and a display device.

### BACKGROUND

Display With Camera (FDC) technology hides the front camera under the display screen, and the area where the camera is set can display the image normally, completely eliminating the bangs and borders in the display product, thus realizing a true full-screen display. However, when display products use this technology, uneven display brightness is prone to occur.

### SUMMARY

The present disclosure is to provide a display substrate and a display device.

In order to achieve the above objectives, the present disclosure provides the following technical solutions:
the present disclosure provides a display substrate, comprising a base substrate, the base substrate comprising a first display area and a second display area; the display substrate further comprising: a plurality of first sub-pixels, a plurality of second sub-pixels and a plurality of virtual sub-pixel driving circuits; the first sub-pixels and the virtual sub-pixel driving circuits are located in the first display area, the first sub-pixels comprising a first sub-pixel driving circuit and a first light-emitting element coupled to each other; the second sub-pixel comprising a second light-emitting element located in the second display area; the plurality of virtual sub-pixel driving circuits comprising a plurality of target virtual sub-pixel driving circuits and a plurality of non-target virtual sub-pixel driving circuits, and part of the target virtual sub-pixel driving circuits are coupled to the corresponding second light-emitting elements through conductive connecting lines;
the plurality of first sub-pixel driving circuits included in the plurality of first sub-pixels can be divided into a plurality of first target sub-pixel driving circuits and a plurality of first non-target sub-pixel driving circuits; the plurality of target virtual sub-pixel driving circuits can be divided into a plurality of target driving circuit rows together with the plurality of first target sub-pixel driving circuits, each of the target driving circuit rows including a first target sub-pixel driving circuit and a target virtual sub-pixel driving circuit; the plurality of first non-target sub-pixel driving circuits and the plurality of non-target virtual sub-pixel driving circuits are divided into a plurality of non-target driving circuit rows, each of the non-target driving circuit rows including a first non-target sub-pixel driving circuit and a non-target virtual sub-pixel driving circuit;
the display substrate further comprises a plurality of first target scanning lines and a plurality of first non-target scanning lines, wherein the first target scanning lines are respectively coupled to each of the target virtual sub-pixel drive circuits and each of the first target sub-pixel drive circuits in the corresponding target drive circuit row; and the first non-target scanning lines are respectively coupled to each of the non-target virtual sub-pixel drive circuits and each of the first non-target sub-pixel drive circuits in the corresponding non-target drive circuit row;
orthographic projection of the conductive connection line on the base substrate at least partially overlaps with the orthographic projection of the first target scanning line on the base substrate;
the gates of the driving transistors in at least part of the sub-pixel driving circuits included in the target driving circuit row are configured to have substantially the same potential as the gates of the driving transistors in at least part of the sub-pixel driving circuits included in the non-target driving circuit row after charging.

Optionally, the display substrate includes a data line and a power line;
a least part of the first target sub-pixel driving circuit and/or at least part of the target virtual sub-pixel driving circuit includes:
The driving transistor and the data writing transistor, wherein the first electrode of the data writing transistor is coupled to the corresponding data line, and the second electrode of the data writing transistor is coupled to the first electrode of the driving transistor;
a first compensation pattern and a second compensation pattern, wherein the first compensation pattern is coupled to the first electrode of the driving transistor, the second compensation pattern is coupled to the corresponding power line, and the orthographic projection of the first compensation pattern on the base substrate at least partially overlaps with the orthographic projection of the second compensation pattern on the base substrate.

Optionally, the data writing transistor includes a fourth active layer, the fourth active layer includes an active main body portion and an active protrusion portion, the active main body portion extends along a first direction, and the active protrusion portion protrudes from the active main body portion along a second direction; the first direction intersects with the second direction;
the first compensation pattern is coupled to the active protrusion, and the first compensation pattern is located on a side of the active protrusion facing away from the base substrate.

Optionally, the display substrate includes a light-shielding layer, an active layer, a first gate metal layer, a second gate metal layer, a first source-drain metal layer, a compensation source-drain metal layer and a second source-drain metal layer, which are stacked in sequence along a direction away from the base substrate, and the first compensation pattern is arranged in the same layer and material as the first source-drain metal layer.

Optionally, the second compensation pattern and the power line coupled thereto form an integrated structure.

Optionally, at least part of the first target sub-pixel driving circuit and/or at least part of the target virtual sub-pixel driving circuit further includes: a storage capacitor, the storage capacitor including a first electrode plate and a second electrode plate arranged opposite to each other, the first electrode plate being located between the base substrate and the second electrode plate;
the orthographic projection of the second electrode plate on the base substrate partially overlaps with the orthographic projection of the active protrusion on the base substrate; or, the orthographic projection of the second electrode plate on the base substrate does not overlap with the orthographic projection of the active protrusion on the base substrate.

Optionally, the orthographic projection of the second electrode plate on the base substrate at least partially overlaps with the orthographic projection of the first compensation pattern on the base substrate.

Optionally, a difference A between a coupling capacitance formed by the first target scanning line and a coupling capacitance formed by the first non-target scanning line satisfies: A≤80 fF.

Optionally, A≤60 fF; or, A≤30 fF.

Optionally, the display substrate also includes a shading layer; the orthographic projection of the first target scanning line on the base substrate and the orthographic projection of the shading layer on the base substrate have a first overlapping area; the orthographic projection of the first non-target scanning line on the base substrate and the orthographic projection of the shading layer on the base substrate have a second overlapping area; the first overlapping area is smaller than the second overlapping area.

Optionally, in at least one first target sub-pixel driving circuit layout area and/or in at least one target virtual sub-pixel driving circuit layout area, the area of the first target scanning line is smaller than the area of the first non-target scanning line in a first non-target sub-pixel driving circuit layout area and/or a non-target virtual sub-pixel driving circuit layout area.

Optionally, at least part of the first target sub-pixel driving circuit, at least part of the target dummy sub-pixel driving circuit, and the first non-target sub-pixel driving circuit and the non-target dummy sub-pixel driving circuit all include a data writing transistor, and the data writing transistor includes a fourth active layer;
the first target scanning line includes a first target main body portion and a first target protrusion portion, the first target main body portion includes at least a portion extending along a second direction, the first target protrusion portion protrudes from the first target main body portion along a first direction, and the first direction intersects the second direction;
the first non-target scanning line includes a first non-target main body portion and a first non-target protrusion portion, the first non-target main body portion includes at least a portion extending along the second direction, and the first non-target protrusion portion protrudes from the first non-target main body portion along the first direction;
the orthographic projection of the first target protrusion on the base substrate at least partially overlaps with the orthographic projection of the fourth active layer in the sub-pixel driving circuit layout area to which it belongs on the base substrate; the orthographic projection of the first non-target protrusion on the base substrate at least partially overlaps with the orthographic projection of the fourth active layer in the sub-pixel driving circuit layout area to which it belongs on the base substrate;
an area of the first target protrusion is smaller than an area of the first non-target protrusion.

Optionally, a width of the first target protrusion along the second direction is smaller than a width of the first non-target protrusion.

Optionally, the first target sub-pixel driving circuit, the target virtual sub-pixel driving circuit, the first non-target sub-pixel driving circuit, and the non-target virtual sub-pixel driving circuit all include: a storage capacitor, the storage capacitor includes a first electrode plate and a second electrode plate that are arranged opposite to each other, the first electrode plate is located between the base substrate and the second electrode plate;
In at least part of the first target sub-pixel driving circuit layout area and/or at least part of the target virtual sub-pixel driving circuit layout area, along the first direction, there is a first distance between the orthographic projection of the first target protrusion on the base substrate and the orthographic projection of the second electrode plate on the base substrate; in the first non-target sub-pixel driving circuit layout area and/or the non-target virtual sub-pixel driving circuit layout area, along the first direction, there is a second distance between the orthographic projection of the first non-target protrusion on the base substrate and the orthographic projection of the second electrode plate on the base substrate; the first distance is greater than the second distance.

Optionally, at least part of the first non-target sub-pixel driving circuit and/or at least part of the non-target virtual sub-pixel driving circuit includes:
a driving transistor and a compensating transistor, wherein a first electrode of the compensating transistor is coupled to a second electrode of the driving transistor, and the second electrode of the compensating transistor is coupled to a gate of the driving transistor via a first conductive connecting portion;
a third compensation pattern is coupled to the first conductive connection portion, and an orthographic projection of the third compensation pattern on the base substrate has a third overlapping area with an orthographic projection of the first non-target scanning line on the base substrate.

Optionally, in at least two non-target drive circuit rows closest to the second display area, the third overlapping area gradually increases along the first direction and along the direction away from the first display area.

Optionally, the third compensation pattern and the first conductive connection portion form an integral structure.

Optionally, the display substrate includes a power line; the first target sub-pixel driving circuit, the target virtual sub-pixel driving circuit and the first non-target sub-pixel driving circuit all include: a storage capacitor and a driving transistor, a first plate of the storage capacitor is coupled to a gate of the driving transistor, and a second plate of the storage capacitor is coupled to a corresponding power line;
a capacitance value of a storage capacitor in at least part of the first target sub-pixel driving circuit and/or at least part of the target virtual sub-pixel driving circuit is smaller than a capacitance value of a storage capacitor in at least part of the first non-target sub-pixel driving circuit.

Optionally, an area of the first plate in at least part of the first target sub-pixel driving circuit and/or at least part of the target virtual sub-pixel driving circuit is smaller than an area of the first plate in at least part of the first non-target sub-pixel driving circuit.

Optionally, the display substrate also includes a shading layer; in at least part of the first target sub-pixel driving circuit and/or at least part of the target virtual sub-pixel driving circuit, there is a fourth overlapping area between the orthographic projection of the first electrode plate on the base substrate and the orthographic projection of the shading layer on the base substrate; in at least part of the first non-target sub-pixel driving circuit, there is a fifth overlapping area between the orthographic projection of the first electrode plate on the base substrate and the orthographic projection of the shading layer on the base substrate; the fourth overlapping area is smaller than the fifth overlapping area.

Optionally, in at least part of the first target sub-pixel driving circuit and/or at least part of the target virtual sub-pixel driving circuit, there is a sixth overlapping area between the orthographic projection of the second electrode plate on the base substrate and the orthographic projection of the power line on the base substrate; in at least part of the first non-target sub-pixel driving circuit, there is a seventh overlapping area between the orthographic projection of the second electrode plate on the base substrate and the orthographic projection of the power line on the base substrate; the sixth overlapping area is smaller than the seventh overlapping area.

Optionally, in at least two non-target drive circuit rows closest to the second display area, the capacitance value of the storage capacitor gradually increases along the first direction and along the direction close to the second display area.

Optionally, the display substrate further includes a compensation planarization layer, and at least a portion of the compensation planarization layer is located between the conductive connection line and the first target scanning line.

Optionally, the display substrate also includes a power line; in at least part of the first target sub-pixel driving circuit layout area and/or at least part of the target virtual sub-pixel driving circuit layout area, an orthographic projection of the power line on the base substrate has an eighth overlapping area with an orthographic projection of the first target scanning line on the base substrate, and the eighth overlapping area is greater than 80% of the area of the first target scanning line in the first target sub-pixel driving circuit layout area, or the eighth overlapping area is greater than 80% of the area of the first target scanning line in the target virtual sub-pixel driving circuit layout area.

Optionally, the display substrate also includes a virtual data line; in at least part of the first target sub-pixel drive circuit layout area and/or at least part of the target virtual sub-pixel drive circuit layout area, the virtual data line has a ninth overlapping area between the orthographic projection of the first target scanning line on the base substrate and the orthographic projection of the first target scanning line on the base substrate, and the ninth overlapping area is greater than 80% of the area of the first target scanning line in the first target sub-pixel drive circuit layout area, or the ninth overlapping area is greater than 80% of the area of the first target scanning line in the target virtual sub-pixel drive circuit layout area.

Based on the technical solution of the above-mentioned display substrate, a second aspect of the present disclosure provides a display device, comprising the above-mentioned display substrate.

### BRIEF DESCRIPTION OF THE DRAWINGS

The drawings described herein are used to provide a further understanding of the present disclosure and constitute a part of the present disclosure. The illustrative embodiments of the present disclosure and their descriptions are used to explain the present disclosure and do not constitute an improper limitation on the present disclosure. In the drawings:

FIG. 1 is a first schematic diagram of a circuit structure of a sub-pixel driving circuit provided in an embodiment of the present disclosure;

FIG. 2 is a schematic structural diagram of a display substrate provided in an embodiment of the present disclosure;

FIG. 3 is a schematic diagram of a first layout of sub-pixel driving circuits in a target driving circuit row provided by an embodiment of the present disclosure;

FIG. 4 is a schematic diagram of the layout of the active layer and the first gate metal layer in FIG. 3;

FIG. 5 is a schematic diagram of the layout of the active layer and the second gate metal layer, the interlayer insulating layer and the first source and drain metal layer in FIG. 3;

FIG. 6 is a schematic diagram of the layout of the active layer and the interlayer insulating layer and the first source-drain metal layer and the compensation source-drain metal layer in FIG. 3;

FIG. 7 is a schematic diagram of a via hole formed on the interlayer insulating layer in FIG. 3;

FIG. 8 is a schematic diagram of the layout of the light shielding layer in FIG. 3;

FIG. 9 is a schematic diagram of the layout of the active layer in FIG. 3;

FIG. 10 is a schematic diagram of the layout of the second gate metal layer in FIG. 3;

FIG. 11 is a schematic diagram of the layout of the first source and drain metal layer in FIG. 3;

FIG. 12 is a schematic diagram of the layout of the compensation source and drain metal layer in FIG. 3;

FIG. 13 is a schematic diagram of the layout of the second source-drain metal layer in FIG. 3;

FIG. 14 is a schematic diagram of a second layout of sub-pixel driving circuits in a target driving circuit row provided by an embodiment of the present disclosure;

FIG. 15 is a schematic diagram of the layout of the light shielding layer and the first gate metal layer in FIG. 14;

FIG. 16 is a schematic diagram of the layout of the first gate metal layer and the second gate metal layer in FIG. 14;

FIG. 17 is a schematic diagram of the compensation source-drain metal layer and the second source-drain metal layer in FIG. 14;

FIG. 18 is a schematic diagram of the layout of the first gate metal layer in FIG. 14;

FIG. 19 is a schematic diagram of the first source-drain metal layer on the interlayer insulating layer in FIG. 14;

FIG. 20 is a schematic diagram of a first layout of sub-pixel driving circuits in a non-target driving circuit row provided by an embodiment of the present disclosure;

FIG. 21 is a schematic diagram of the layout of the first gate metal layer and the first source and drain metal layer in FIG. 20;

FIG. 22 is a schematic diagram of the layout of the active layer in FIG. 20;

FIG. 23 is a schematic diagram of the layout of the first gate metal layer in FIG. 20;

FIG. 24 is a schematic diagram of the layout of the second gate metal layer in FIG. 20;

FIG. 25 is a schematic diagram of the layout of the first source and drain metal layer in FIG. 20;

FIG. 26 is a schematic diagram of a third layout of sub-pixel driving circuits in a target driving circuit row provided by an embodiment of the present disclosure;

FIG. 27 is a schematic diagram of the layout of the first gate metal layer and the second gate metal layer in FIG. 26;

FIG. 28 is a schematic diagram of a compensation source and drain metal layer are added on the basis of FIG. 27;

FIG. 29 is a schematic diagram of the layout of the light shielding layer in FIG. 26;

FIG. 30 is a schematic diagram of the compensation source and drain metal layer in FIG. 26;

FIG. 31 is a schematic diagram of a second layout of sub-pixel driving circuits in a non-target driving circuit row provided by an embodiment of the present disclosure;

FIG. 32 is a schematic diagram of the layout of the first gate metal layer and the second gate metal layer in FIG. 31;

FIG. 33 is a schematic diagram of a layout in which a light shielding layer and a compensation source and drain metal layer are added on the basis of FIG. 32;

FIG. 34 is a schematic diagram of the layout of the first gate metal layer in FIG. 31;

FIG. 35 is a schematic diagram of the layout of the second gate metal layer in FIG. 31;

FIG. 36 is a schematic diagram of the compensation source and drain metal layer in FIG. 31;

FIG. 37 is a schematic diagram of a fourth layout of sub-pixel driving circuits in a target driving circuit row provided by an embodiment of the present disclosure;

FIG. 38 is a schematic diagram of the layout of the first gate metal layer and the compensation source and drain metal layer in FIG. 37;

FIG. 39 is a schematic diagram of the layout of the first gate metal layer and the second source/drain metal layer in FIG. 37;

FIG. 40 is a schematic diagram of the compensation source and drain metal layer in FIG. 37;

FIG. 41 is a schematic diagram of the layout of the second source-drain metal layer in FIG. 37;

FIG. 42 is a cross-sectional schematic diagram of each film layer in a display substrate provided in an embodiment of the present disclosure; and

FIG. 43 is a second schematic diagram of the circuit structure of the sub-pixel driving circuit provided in an embodiment of the present disclosure.

### DETAILED DESCRIPTION

In order to further illustrate the display substrate and the display device provided by the embodiments of the present disclosure, a detailed description is given below in conjunction with the accompanying drawings.

Based on the technical problems existing in the background technology, it is found through research that when the display product adopts the FDC technology, the FDC area where the camera is set only retains the light-emitting element, and the signal controlling the light-emitting element to emit light is provided by the sub-pixel driving circuit in the same horizontal row, and the sub-pixel driving circuit is located in the normal display area, and the normal display area is located around the FDC area. The light-emitting element located in the FDC area needs to be coupled to the sub-pixel driving circuit through a longer conductive connecting line. The conductive connecting line will overlap with the scanning line coupled with the sub-pixel driving circuit to form a coupling capacitor (the capacitance is generally 560 fF˜750 fF), thereby increasing the loading of the scanning line, reducing the charging time, resulting in insufficient voltage at the N1 node (i.e., the gate of the driving transistor in the sub-pixel driving circuit), which in turn causes the normal display area in the same row as the FDC area to be brighter, and the horizontal stripe Mura in the row where the FDC area is located appears.

Further verification found that at 120 Hz (charging time 2.6 μs), the horizontal mura corresponding to the row where the FDC area is located is bright; at 90 Hz (charging time 3.5 μs), the horizontal mura is similar to the normal display brightness; at 60 Hz (charging time 4.8 μs), the horizontal mura is slightly dark, that is, the horizontal mura is related to the charging time and the loading intensity of the scanning line.

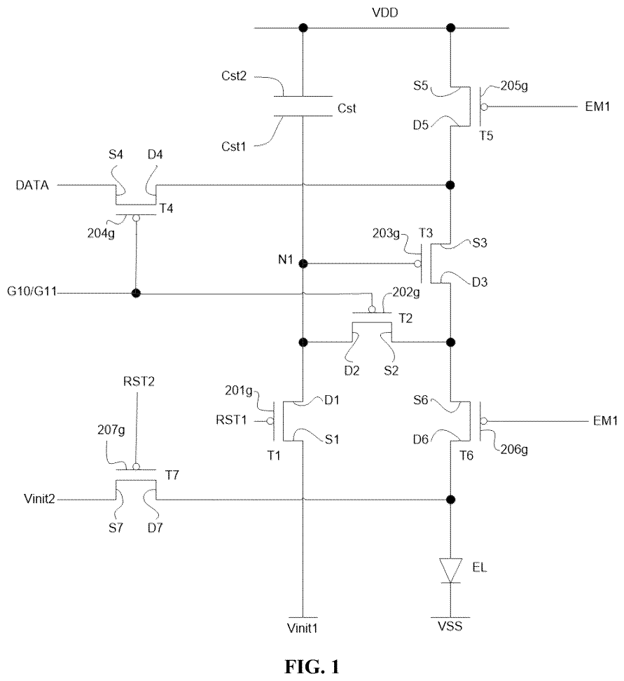

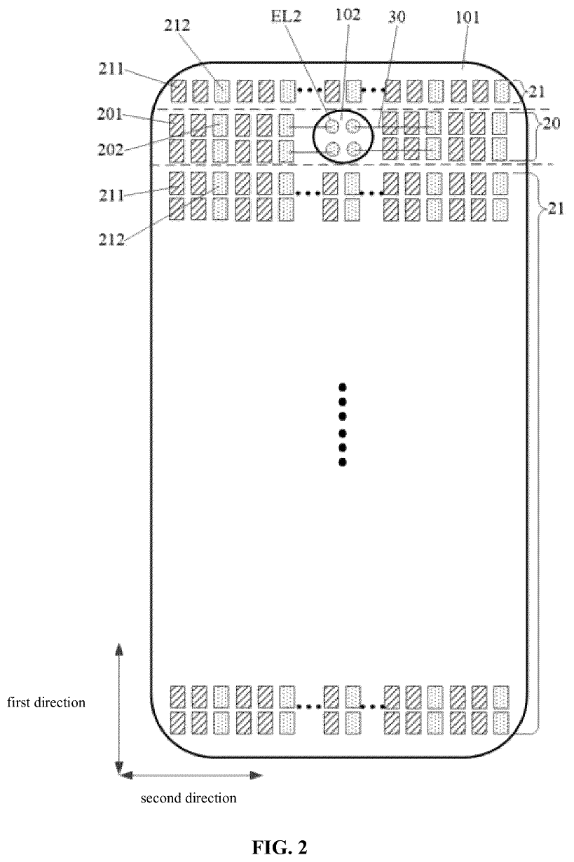

Referring to FIG. 1 and FIG. 2, an embodiment of the present disclosure provides a display substrate, including a base substrate, the base substrate including a first display area 101 and a second display area 102; the display substrate further includes: a plurality of first sub-pixels, a plurality of second sub-pixels and a plurality of virtual sub-pixel driving circuits; the first sub-pixels and the virtual sub-pixel driving circuits are located in the first display area 101, the first sub-pixels include a first sub-pixel driving circuit and a first light-emitting element coupled to each other; the second sub-pixel includes a second light-emitting element EL2 located in the second display area 102; the plurality of virtual sub-pixel driving circuits include a plurality of target virtual sub-pixel driving circuits 202 and a plurality of non-target virtual sub-pixel driving circuits 212, and part of the target virtual sub-pixel driving circuits 202 are coupled to the corresponding second light-emitting elements EL2 through conductive connecting lines 30.

The plurality of first sub-pixel driving circuits included in the plurality of first sub-pixels can be divided into a plurality of first target sub-pixel driving circuits 201 and a plurality of first non-target sub-pixel driving circuits 211; the plurality of target virtual sub-pixel driving circuits 202 can be divided into a plurality of target driving circuit rows 20 together with the plurality of first target sub-pixel driving circuits 201, and each of the target driving circuit rows 20 includes a first target sub-pixel driving circuit 201 and a target virtual sub-pixel driving circuit 202; the plurality of first non-target sub-pixel driving circuits 211 and the plurality of non-target virtual sub-pixel driving circuits 212 are divided into a plurality of non-target driving circuit rows 21, and each of the non-target driving circuit rows 21 includes a first non-target sub-pixel driving circuit 211 and a non-target virtual sub-pixel driving circuit 212.

The display substrate further includes a plurality of first target scanning lines G10 and a plurality of first non-target scanning lines G11, wherein the first target scanning lines G10 are respectively coupled to each of the target virtual sub-pixel drive circuits 202 and each of the first target sub-pixel drive circuits 201 in the corresponding target drive circuit row 20; the first non-target scanning lines G11 are respectively coupled to each of the non-target virtual sub-pixel drive circuits 212 and each of the first non-target sub-pixel drive circuits 211 in the corresponding non-target drive circuit row 21;
the orthographic projection of conductive connection line 30 on the base substrate at least partially overlaps with the orthographic projection of the first target scanning line G10 on the base substrate.

The gates 203g of the driving transistors in at least part of the sub-pixel driving circuits included in the target driving circuit row 20 are configured to have substantially the same potential as the gates 203g of the driving transistors in at least part of the sub-pixel driving circuits included in the non-target driving circuit row 21 after charging.

Exemplarily, the base substrate includes a first display area 101 and a second display area 102, the second display area 102 includes the FDC area, the second display area 102 is used to set a sensor, the sensor is located on the non-display surface side of the display substrate, and the sensor overlaps the second display area 102 of the display substrate in the orthographic projection of the display substrate. The sensor includes a camera, a photosensitive element, a photosensitive device, a sensor, an optical member, an optical device, a camera, a photosensitive component, an optical sensor, a sensing module, a flash, a proximity sensor, and an illumination sensor.

Exemplarily, the first display area 101 is located at the periphery of the second display area 102, the first display area 101 may be located on one side of the second display area 102, or the first display area 101 at least partially surrounds the second display area 102, or the first display area 101 completely surrounds the second display area 102.

Exemplarily, the first light emitting element and the second light emitting element EL2 each include an anode layer, a light emitting functional layer and a cathode layer which are stacked, wherein the anode layer is coupled to a corresponding sub-pixel driving circuit and receives a driving signal provided by the sub-pixel driving circuit.

Exemplarily, the conductive connection line 30 includes a transparent conductive connection line 30, which is beneficial to improving the transmittance of the second display area 102. The conductive connection line 30 is made of a transparent conductive material, such as indium tin oxide material, but not limited thereto.

Exemplarily, the first target sub-pixel driving circuit 201 and the first non-target sub-pixel driving circuit 211 have the same structure, and only differ in their layout positions in the first display area 101.

Exemplarily, the circuit structure of the target virtual sub-pixel driving circuit 202 is the same as that of the non-target virtual sub-pixel driving circuit 212, and the only difference is the layout position in the first display area 101. It is worth noting that the target virtual sub-pixel driving circuit 202 coupled to the second light-emitting element EL2 is coupled to the data line DATA capable of transmitting a data signal. The other target virtual sub-pixel driving circuits 202 and the non-target virtual sub-pixel driving circuits 212 are coupled to a virtual data line, which is coupled to the power line VDD.

Exemplarily, the plurality of target driving circuit rows 20 are arranged along a first direction, and each of the plurality of target driving circuit rows 20 includes a plurality of first target sub-pixel driving circuits 201 and a plurality of target virtual sub-pixel driving circuits 202.

Exemplarily, the plurality of non-target driving circuit rows 21 are located at one side of the plurality of target driving circuit rows 20. Alternatively, the plurality of non-target driving circuit rows 21 are divided into two groups, and the plurality of target driving circuit rows 20 are located between the two groups.

Exemplarily, the target driving circuit row 20 is laid out in a two-in-one or four-in-one layout, where two-in-one means two first target sub-pixel driving circuits 201 and one target virtual sub-pixel driving circuit 202 are alternately arranged, and four-in-one means four first target sub-pixel driving circuits 201 and one target virtual sub-pixel driving circuit 202 are alternately arranged. Similarly, the non-target driving circuit row 21 may also be laid out in the above-mentioned two-in-one or four-in-one layout, but is not limited thereto.

Exemplarily, the first target scanning line G10 is coupled to the gate of the compensation transistor included in each of the target virtual sub-pixel driving circuits 202 in the corresponding target driving circuit row 20, and the gate of the data writing transistor. The first target scanning line G10 is also coupled to the gate of the compensation transistor included in each of the first target sub-pixel driving circuits 201 in the corresponding target driving circuit row 20, and the gate of the data writing transistor.

Exemplarily, the first non-target scanning line G11 is coupled to the gate of the compensation transistor included in each of the first non-target sub-pixel driving circuits 211 in the corresponding non-target driving circuit row 21, and the gate of the data writing transistor. The first non-target scanning line G11 is coupled to the gate of the compensation transistor included in each of the non-target virtual sub-pixel driving circuits 212 in the corresponding non-target driving circuit row 21, and the gate of the data writing transistor.

Exemplarily, the conductive connection line 30 includes at least a portion extending along the second direction. The first target scanning line G10 includes at least a portion extending along the second direction. The first non-target scanning line G11 includes at least a portion extending along the second direction. The first direction intersects the second direction. The first direction includes a longitudinal direction, and the second direction includes a transverse direction.

Exemplarily, each target drive circuit row 20 corresponds to at least one conductive connection line 30. Among all the conductive connection lines 30 corresponding to each target drive circuit row 20, the orthographic projection of at least one conductive connection line 30 on the base substrate at least partially overlaps with the orthographic projection of the first target scanning line G10 on the base substrate.

Exemplarily, after the target drive circuit row 20 and the non-target drive circuit row 21 finish charging, the gate 203g potential of the drive transistor in at least part of the sub-pixel drive circuits included in the target drive circuit row 20 is substantially equal to the gate 203g potential of the drive transistor in at least part of the sub-pixel drive circuits included in the non-target drive circuit row 21. It should be noted that at least part of the sub-pixel drive circuits included in the target drive circuit row 20 include a target virtual sub-pixel drive circuit 202 and/or a first target sub-pixel drive circuit 201. At least part of the sub-pixel drive circuits included in the non-target drive circuit row 21 include a non-target virtual sub-pixel drive circuit 212 and/or a first non-target sub-pixel drive circuit 211.

According to the specific structure of the above-mentioned display substrate, in the display substrate provided by the embodiment of the present disclosure, the orthographic projection of the conductive connection line 30 on the base substrate at least partially overlaps with the orthographic projection of the first target scanning line G10 on the base substrate 10, which will affect the charging time of the sub-pixel driving circuit. By setting the gate 203g potential of the driving transistor in at least part of the sub-pixel driving circuits included in the target driving circuit row 20 and the non-target driving circuit row 21 after the charging is completed, it is equal to the gate 203g potential of the driving transistor in at least part of the sub-pixel driving circuits included in the non-target driving circuit row 21, thereby compensating for the influence of insufficient charging time, effectively improving the horizontal stripe Mura of the row where the second display area 102 is located, and ensuring the brightness uniformity of the display substrate.

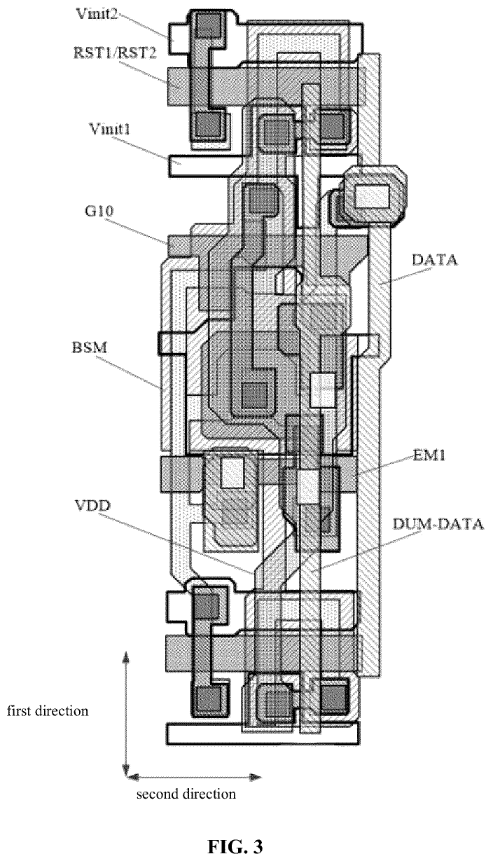

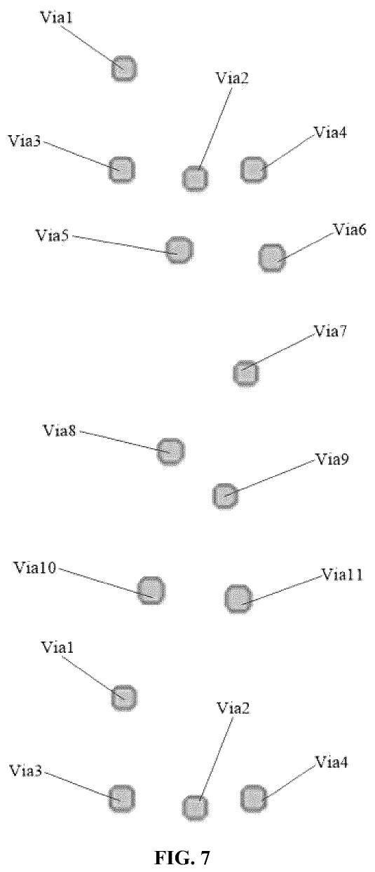

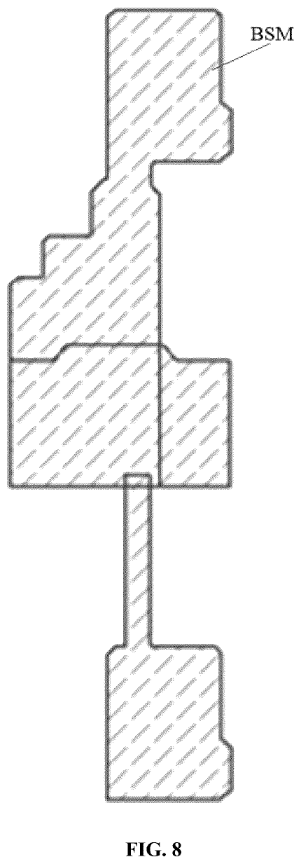

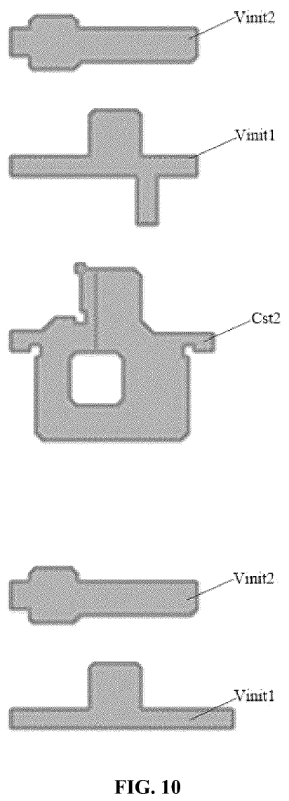

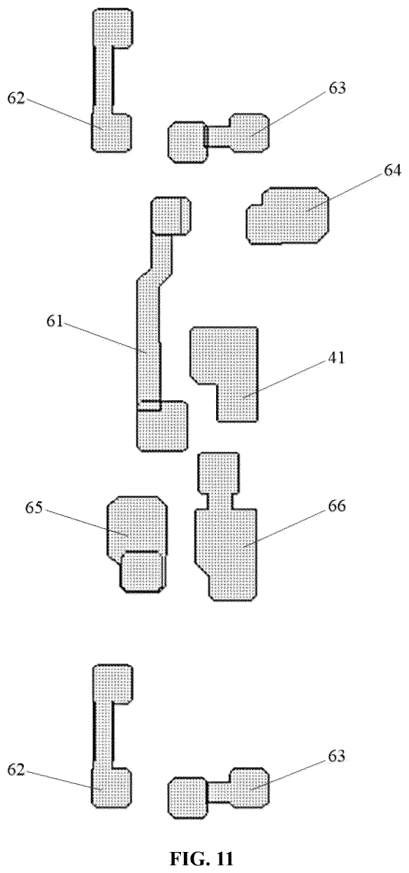

As shown in FIGS. 1 to 13 and 43, in some embodiments, the display substrate includes a data line DATA and a power line VDD;
at least part of the first target sub-pixel driving circuit 201 and/or at least part of the target virtual sub-pixel driving circuit 202 includes:
a driving transistor (i.e., a third transistor T3) and a data writing transistor (i.e., a fourth transistor T4), wherein a first electrode of the data writing transistor is coupled to the corresponding data line, and a second electrode of the data writing transistor is coupled to a first electrode of the driving transistor;
a first compensation pattern 41 and a second compensation pattern 42, wherein the first compensation pattern 41 is coupled to the first electrode of the driving transistor, and the second compensation pattern 42 is coupled to the corresponding power line VDD, and the orthographic projection of the first compensation pattern 41 on the base substrate 10 and the orthographic projection of the second compensation pattern 42 on the base substrate at least partially overlap.

Exemplarily, the display substrate includes a plurality of data lines DATA and a plurality of power lines VDD, the plurality of data lines DATA are arranged along the second direction, the plurality of power lines VDD are arranged along the second direction, the data lines include at least a portion extending along the first direction, and the power lines VDD include at least a portion extending along the first direction.

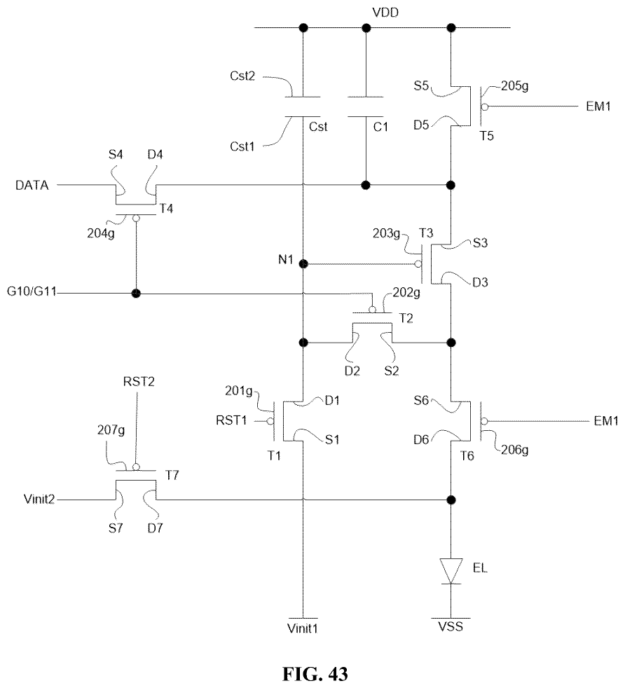

Exemplarily, at least part of the first target sub-pixel driving circuit 201 and/or at least part of the target virtual sub-pixel driving circuit 202 is configured to include: the first compensation pattern 41 and the second compensation pattern 42, so that at least part of the first target sub-pixel driving circuit 201 and/or at least part of the target virtual sub-pixel driving circuit 202 is formed into a circuit structure of 7T2C (including 7 transistors and 2 capacitors). As shown in FIG. 43, it is equivalent to adding a capacitor C1.

In the display substrate provided in the above embodiment, by setting the first compensation pattern 41 and the second compensation pattern 42, a capacitor structure is formed between the first compensation pattern 41 and the second compensation pattern 42, and the capacitor structure is connected between the power line VDD and the first electrode of the driving transistor, so that the data signal transmitted by the data line can be stored in the capacitor structure, and after the data signal transmitted by the data line cannot be written into the gate 203g of the driving transistor, the capacitor stored in the capacitor structure can also be continuously written into the gate 203g of the driving transistor, so that the voltage of the gate 203g of the driving transistor increases. Therefore, setting at least part of the first target sub-pixel driving circuit 201 and/or at least part of the target virtual sub-pixel driving circuit 202 includes: the first compensation pattern 41 and the second compensation pattern 42, which is equivalent to extending the charging time of the target driving circuit line 20, and improving the potential of the gate 203g of the driving transistor, thereby effectively improving the horizontal stripe brightness phenomenon.

As shown in FIGS. 1 to 13, in some embodiments, the data writing transistor includes a fourth active layer 54, the fourth active layer 54 includes an active main body portion 540 and an active protrusion portion 541, the active main body portion 540 extends along a first direction, and the active protrusion portion 541 protrudes from the active main body portion 540 along a second direction; the first direction intersects with the second direction;
the first compensation pattern 41 is coupled to the active protrusion 541. The first compensation pattern 41 is located on a side of the active protrusion 541 facing away from the base substrate 10.

Illustratively, the active main body portion 540 forms a first electrode, a second electrode and a channel portion of the data writing transistor, and the active protrusion 541 is coupled to the second electrode.

Exemplarily, an orthographic projection of the first compensation pattern 41 on the base substrate has an overlapping area with an orthographic projection of the active protrusion 541 on the base substrate, and the first compensation pattern 41 and the active protrusion 541 are coupled through a via in the overlapping area.

Exemplarily, the display substrate includes a light shielding layer, an active layer, a first gate metal layer, a second gate metal layer, a first source-drain metal layer, a compensation source-drain metal layer, and a second source-drain metal layer, which are sequentially stacked in a direction away from the base substrate, and the first compensation pattern 41 is provided in the same layer and material as the first source-drain metal layer. In this way, the first compensation pattern 41 can be formed simultaneously with the first source-drain metal layer in the same patterning process.

Exemplarily, the second compensation pattern 42 and the power line VDD coupled thereto form an integral structure.

In the above embodiment, limited layout space is reasonably utilized, thereby reducing the layout difficulty of the display substrate.

As shown in FIGS. 1 to 13 and 42, in some embodiments, at least part of the first target sub-pixel driving circuit 201 and/or at least part of the target virtual sub-pixel driving circuit 202 further includes: a storage capacitor Cst, the storage capacitor Cst includes a first electrode plate Cst1 and a second electrode plate Cst2 that are oppositely arranged, the first electrode plate Cst1 is located between the base substrate 10 and the second electrode plate Cst2;
The orthographic projection of the second electrode plate Cst2 on the base substrate 10 partially overlaps with the orthographic projection of the active protrusion 541 on the base substrate 10; or, the orthographic projection of the second electrode plate Cst2 on the base substrate 10 does not overlap with the orthographic projection of the active protrusion 541 on the base substrate 10.

Exemplarily, the first electrode plate Cst1 is multiplexed as the gate 203g of the driving transistor.

Exemplarily, the orthographic projection of the second electrode plate Cst2 on the base substrate 10 at least partially overlaps with the orthographic projection of the first compensation pattern 41 on the base substrate 10.

Exemplarily, by reducing the area of the second electrode plate Cst2, the orthographic projection of the second electrode plate Cst2 on the base substrate 10 partially overlaps with the orthographic projection of the active protrusion 541 on the base substrate 10, or the orthographic projection of the second electrode plate Cst2 on the base substrate 10 does not overlap with the orthographic projection of the active protrusion 541 on the base substrate 10.

The above configuration effectively reduces the coupling capacitance formed between the second electrode plate Cst2 and the active protrusion 541, which is beneficial to the stability of the operation of the sub-pixel driving circuit.

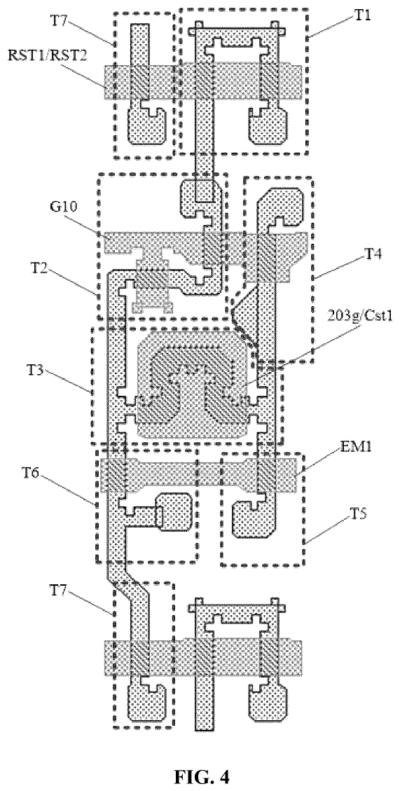

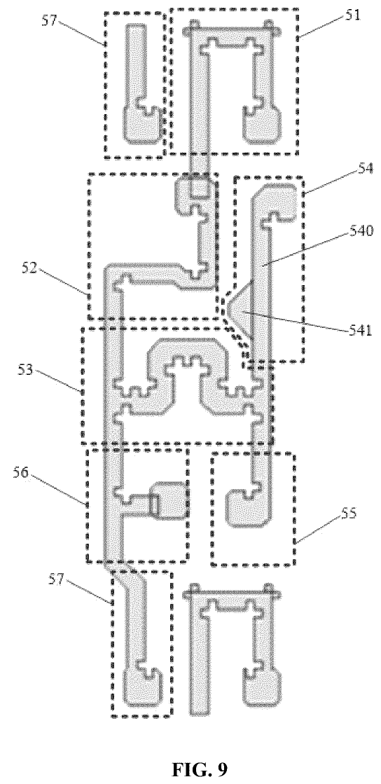

It should be noted that, as shown in FIG. 9, the figure schematically shows the first active layer 51, the second active layer 52, the third active layer 53, the fourth active layer 54, the fifth active layer 55, the sixth active layer 56 and the seventh active layer 57. As shown in FIG. 4 and FIG. 9, the overlapping part of the orthographic projection of each active layer in FIG. 9 on the base substrate and the orthographic projection of the first gate metal layer in FIG. 4 on the base substrate forms a corresponding channel part, and the non-overlapping part of the orthographic projection of each active layer in FIG. 9 on the base substrate and the orthographic projection of the first gate metal layer in FIG. 4 on the base substrate forms the first and second electrodes of the corresponding transistor, as well as the conductor part for connecting the channel part in some dual-gate transistors.

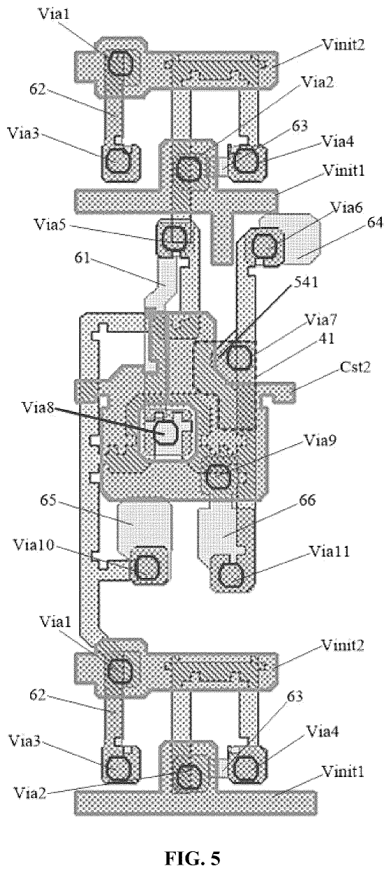

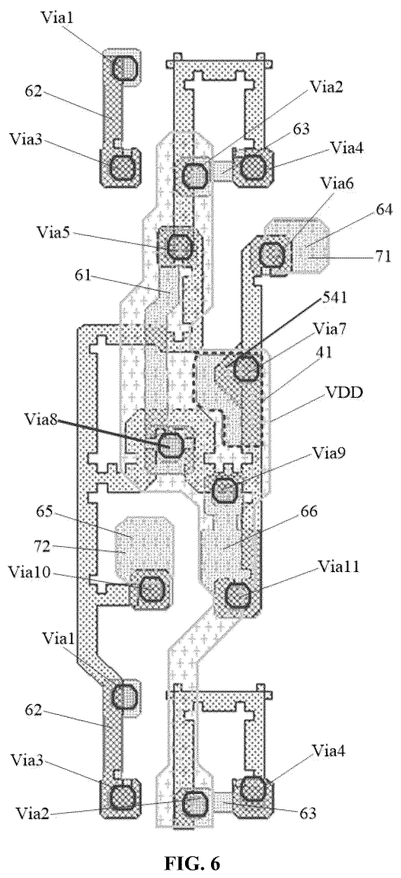

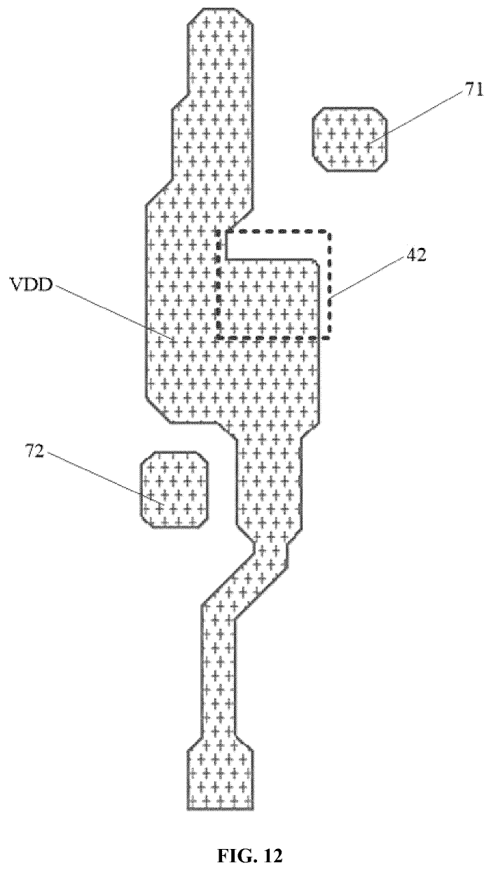

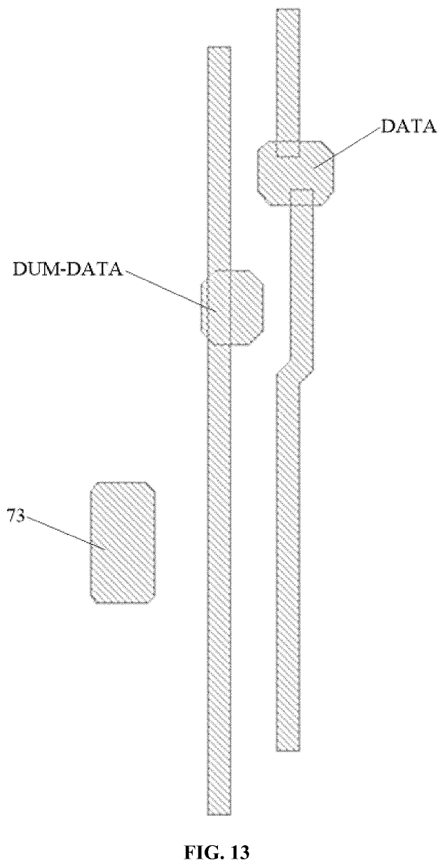

Referring to FIG. 5, FIG. 6, FIG. 12 and FIG. 13, the first conductive connection portion 61 is coupled to the second electrode of the first transistor T1 through the fifth via hole Via5, and the first conductive connection portion 61 is coupled to the gate 203g of the third transistor T3 through the eighth via hole Via8. The second conductive connection portion 62 is coupled to the second initialization signal line Vinit2 through the first via hole Via1, and the second conductive connection portion 62 is coupled to the first electrode of the seventh transistor T7 through the third via hole Via3. The third conductive connection portion 63 is coupled to the first electrode of the first transistor T1 through the fourth via hole Via4, and the third conductive connection portion 63 is coupled to the first initialization signal line Vinit through the second via hole Via2. The fourth conductive connection portion 64 is coupled to the first electrode of the fourth transistor through the sixth via hole Via6, and the fourth conductive connection portion 64 is also coupled to the data line DATA through the eighth conductive connection portion 71. The fifth conductive connection portion 65 is coupled to the second electrode of the sixth transistor T6 through the tenth via hole Via10, and the fifth conductive connection portion 65 is also coupled to the anode pattern through the ninth conductive connection portion 72 and the tenth conductive connection portion 73 in sequence. The sixth conductive connection portion 66 is coupled to the second electrode plate Cst2 through the ninth via hole Via9, and the sixth conductive connection portion 66 is coupled to the first electrode of the fifth transistor T5 through the eleventh via hole Via11. The sixth conductive connection portion 66 is coupled to the power line VDD. The first compensation pattern 41 is coupled to the fourth active layer 54 through the seventh via hole Via7.

The first compensation pattern 41 is coupled to the first electrode of the fifth transistor T5 through the eleventh via hole Via11. The seventh conductive connection portion 67 is coupled to the second electrode plate Cst2 through the ninth via hole Via9.

It is worth noting that in each embodiment, the same single-layer diagram can refer to each other and is not repeatedly illustrated in the drawings.

In some embodiments, the coupling capacitance formed by the first target scanning line G10 is substantially the same as the coupling capacitance formed by the first non-target scanning line G11.

It should be noted that the “substantially the same” means that the difference between the brightness of the light-emitting element driven by the target drive circuit row 20 under the coupling capacitance formed by the first target scanning line G10 and the brightness of the light-emitting element driven by the non-target drive circuit row 21 under the coupling capacitance formed by the first non-target scanning line G11 is less than 5%.

The above configuration avoids the difference in charging time caused by the difference between the coupling capacitance formed by the first target scanning line G10 and the coupling capacitance formed by the first non-target scanning line G11, thereby ensuring the brightness uniformity of the display substrate.

The coupling capacitance formed by the first target scanning line G10 can be reduced or the coupling capacitance formed by the first non-target scanning line G11 can be increased so that the coupling capacitance formed by the first target scanning line G10 is substantially the same as the coupling capacitance formed by the first non-target scanning line G11.

The coupling capacitance formed by the first target scanning line G10 can be gradually reduced along the first direction and along the direction from the second display area 102 to the first display area 101; or, the coupling capacitance formed by the first non-target scanning line G11 can be gradually increased along the first direction and along the direction from the first display area 101 to the second display area 102; thereby, transitional compensation is performed on the coupling capacitance formed by the first target scanning line G10 or the coupling capacitance formed by the first non-target scanning line G11, so that the brightness of the bright boundary shows a gradual trend, thereby reducing the brightness difference between the horizontal stripe and other areas.

In some embodiments, a difference A between a coupling capacitance formed by the first target scanning line and a coupling capacitance formed by the first non-target scanning line satisfies: A≤80 fF.

In some embodiments, A≤60 fF; or, A≤30 fF.

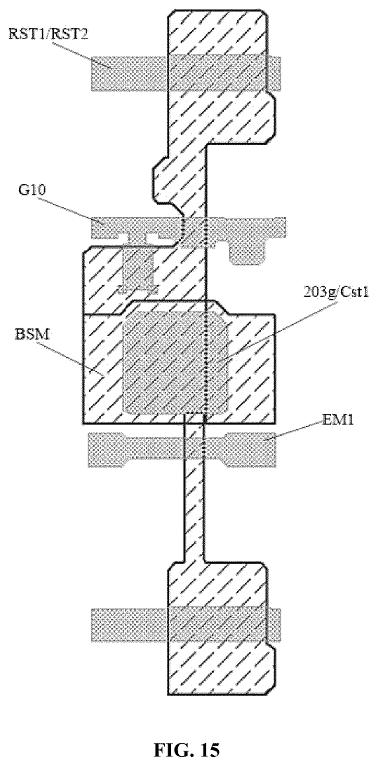

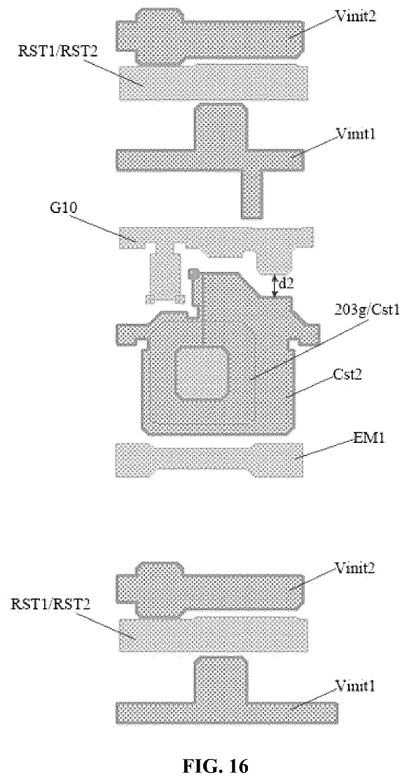

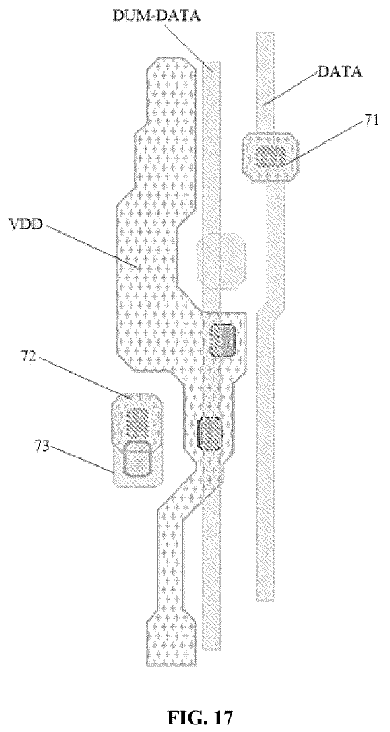

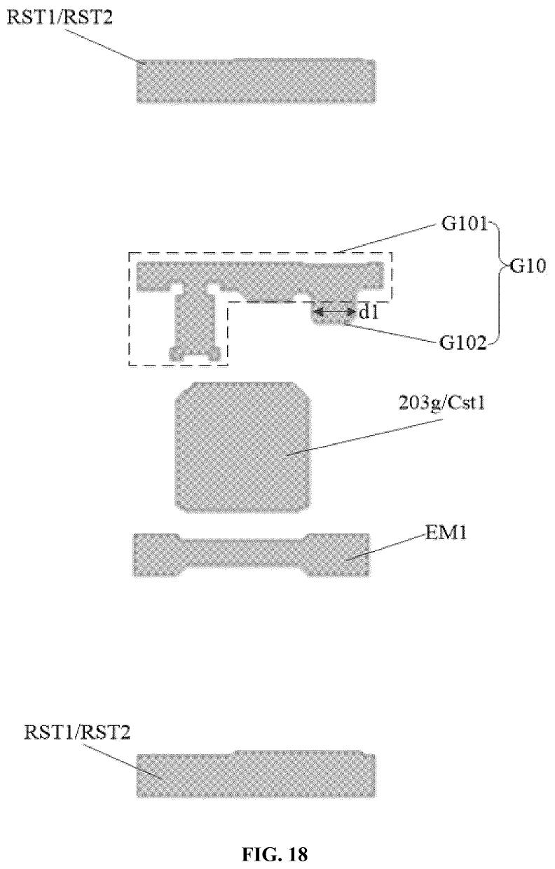

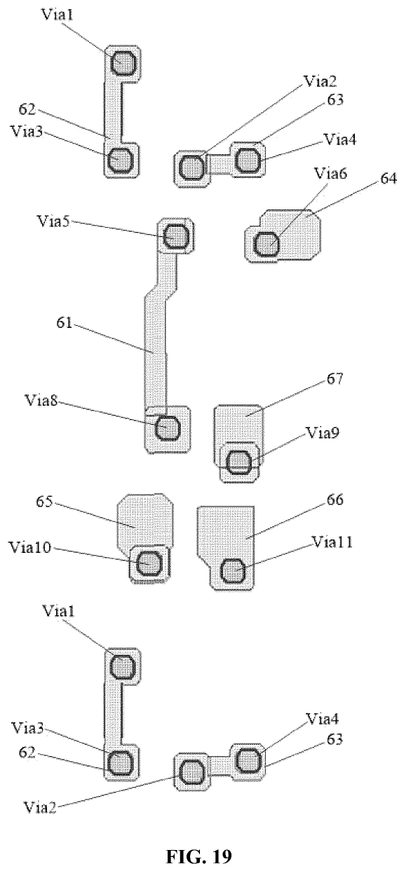

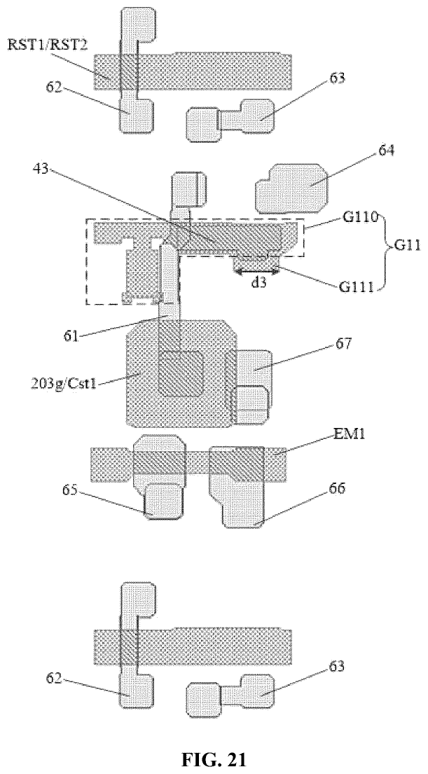

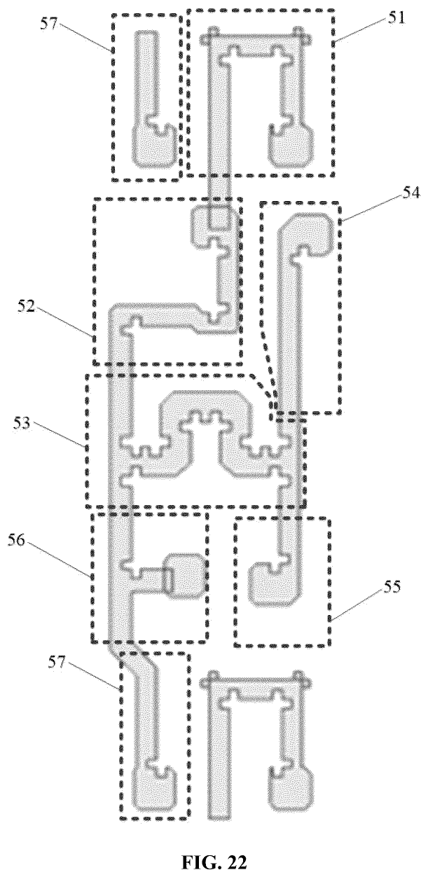

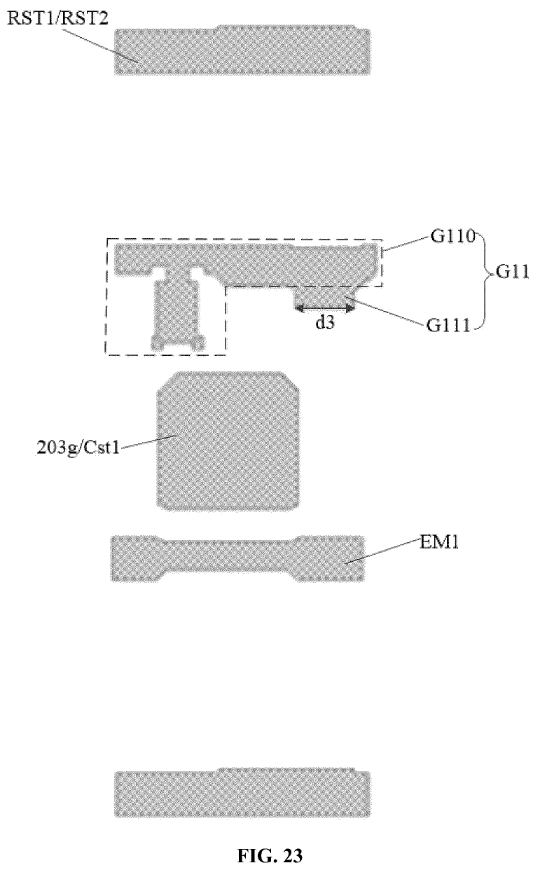

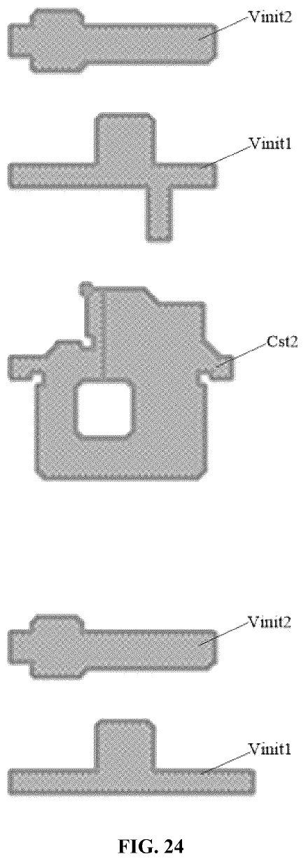

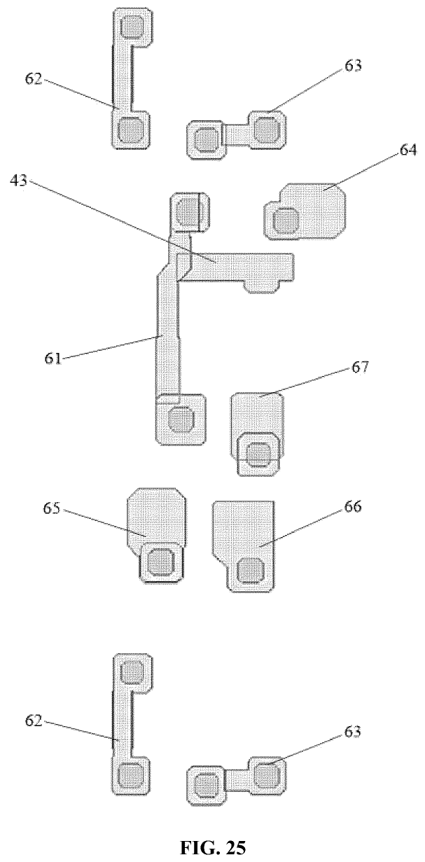

As shown in FIGS. 1, 2, 14 to 19, 20 to 25, and 42, in some embodiments, the display substrate also includes a light-shielding layer BSM; the orthographic projection of the first target scanning line G10 on the base substrate 10 and the orthographic projection of the light-shielding layer BSM on the base substrate 10 have a first overlapping area; the orthographic projection of the first non-target scanning line G11 on the base substrate 10 and the orthographic projection of the light-shielding layer BSM on the base substrate 10 have a second overlapping area; the first overlapping area is smaller than the second overlapping area.

Exemplarily, the light shielding layer BSM is located between the active layer of the display substrate and the base substrate 10.

Exemplarily, the first overlapping area may be smaller than the second overlapping area by adjusting the area or layout structure of the light shielding layer BSM.

For example, the first overlapping area may be smaller than the second overlapping area by reducing the first overlapping area and/or increasing the second overlapping area.

The above-mentioned setting method reduces the coupling capacitance formed by the first target scanning line G10, so that the coupling capacitance formed by the first target scanning line G10 is substantially the same as the coupling capacitance formed by the first non-target scanning line G11, thereby avoiding the difference in charging time caused by the difference between the coupling capacitance formed by the first target scanning line G10 and the coupling capacitance formed by the first non-target scanning line G11, and ensuring the brightness uniformity of the display substrate.

As shown in FIGS. 1, 2, 14 to 19, 20 to 25, and 42, in some embodiments, in at least one first target sub-pixel drive circuit layout area and/or in at least one target virtual sub-pixel drive circuit layout area, the area of the first target scanning line G10 is smaller than the area of the first non-target scanning line G11 in a first non-target sub-pixel drive circuit layout area and/or a non-target virtual sub-pixel drive circuit layout area.

It should be noted that the layout area refers to an area used for laying out the sub-pixel driving circuit, and the area may be a rectangular area that can accommodate the sub-pixel driving circuit, but is not limited thereto.

By setting the area of the first target scanning line G10 to be smaller than the area of the first non-target scanning line G11 in a first non-target sub-pixel driving circuit layout area and/or a non-target virtual sub-pixel driving circuit layout area, the first overlapping area is achieved to be smaller than the second overlapping area.

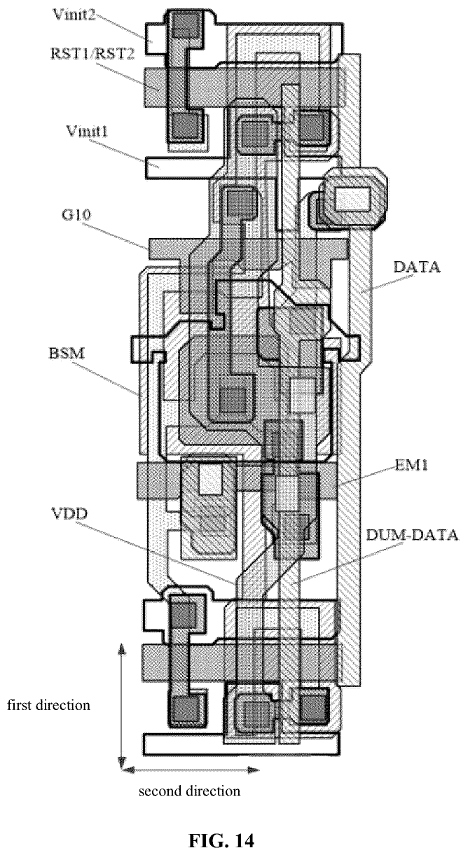

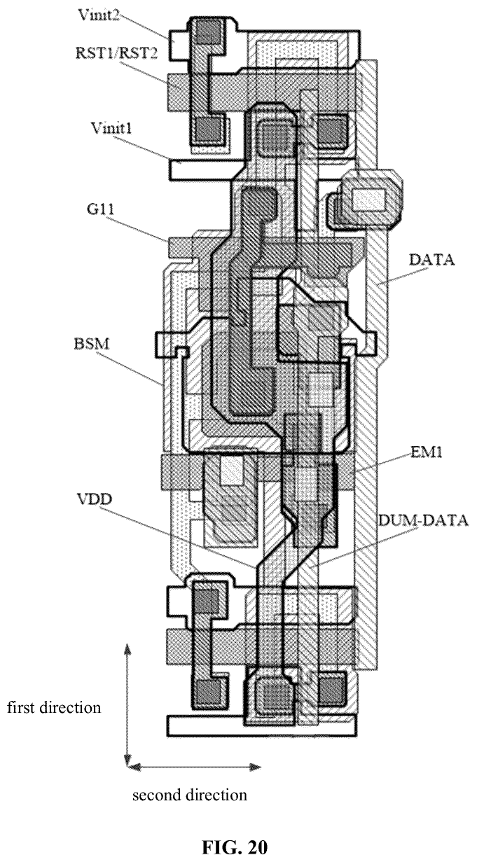

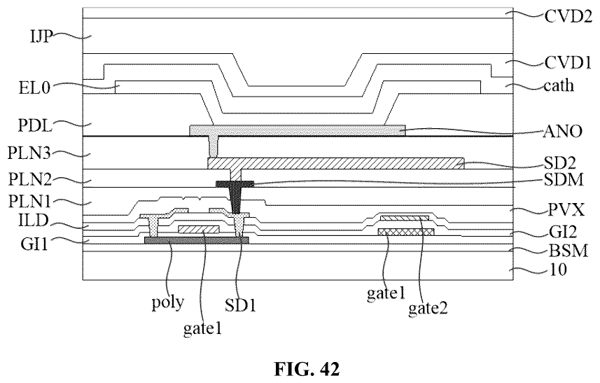

As shown in FIG. 1, FIG. 2, FIG. 14 to FIG. 19, FIG. 20 to FIG. 25, and FIG. 42, in some embodiments, at least part of the first target sub-pixel driving circuit 201, at least part of the target dummy sub-pixel driving circuit 202, and the first non-target sub-pixel driving circuit 211 and the non-target dummy sub-pixel driving circuit 212 all include a data writing transistor, and the data writing transistor includes a fourth active layer 54;

The first target scanning line G10 includes a first target main body G101 and a first target protruding portion G102, the first target main body G101 includes at least a portion extending along a second direction, the first target protruding portion G102 protrudes from the first target main body G101 along a first direction, and the first direction intersects with the second direction;

The first non-target scanning line G11 includes a first non-target main body G110 and a first non-target protrusion G111, the first non-target main body G110 includes at least a portion extending along the second direction, and the first non-target protrusion G111 protrudes from the first non-target main body G110 along the first direction;

The orthographic projection of the first target protrusion G102 on the base substrate 10 at least partially overlaps with the orthographic projection of the fourth active layer 54 in the sub-pixel driving circuit layout area (the first target sub-pixel driving circuit layout area and/or the target virtual sub-pixel driving circuit layout area) to which it belongs on the base substrate 10; the orthographic projection of the first non-target protrusion G111 on the base substrate 10 at least partially overlaps with the orthographic projection of the fourth active layer 54 in the sub-pixel driving circuit layout area (the first non-target sub-pixel driving circuit layout area and/or the non-target virtual sub-pixel driving circuit layout area) to which it belongs on the base substrate 10;

The area of the first target protrusion G102 is smaller than the area of the first non-target protrusion G111.

Exemplarily, the area of the channel portion of the data write transistor in the first sub-pixel driving circuit is equal to the area of the channel portion of the data write transistor in the target virtual sub-pixel driving circuit 202.

Exemplarily, the area of the channel portion of the compensation transistor in the first sub-pixel driving circuit is equal to the area of the channel portion of the compensation transistor in the target virtual sub-pixel driving circuit 202.

Exemplarily, by setting the width d1 of the first target protrusion G102 along the second direction to be smaller than the width d3 of the first non-target protrusion G111, the area of the first target protrusion G102 is smaller than the area of the first non-target protrusion G111.

As shown in FIG. 1, FIG. 2, FIG. 14 to FIG. 19, FIG. 20 to FIG. 25, and FIG. 42, in some embodiments, the first target sub-pixel driving circuit 201, the target virtual sub-pixel driving circuit 202, the first non-target sub-pixel driving circuit 211, and the non-target virtual sub-pixel driving circuit 212 all include: a storage capacitor Cst, the storage capacitor Cst includes a first electrode plate Cst1 and a second electrode plate Cst2 that are oppositely arranged, the first electrode plate Cst1 is located between the base substrate 10 and the second electrode plate Cst2;

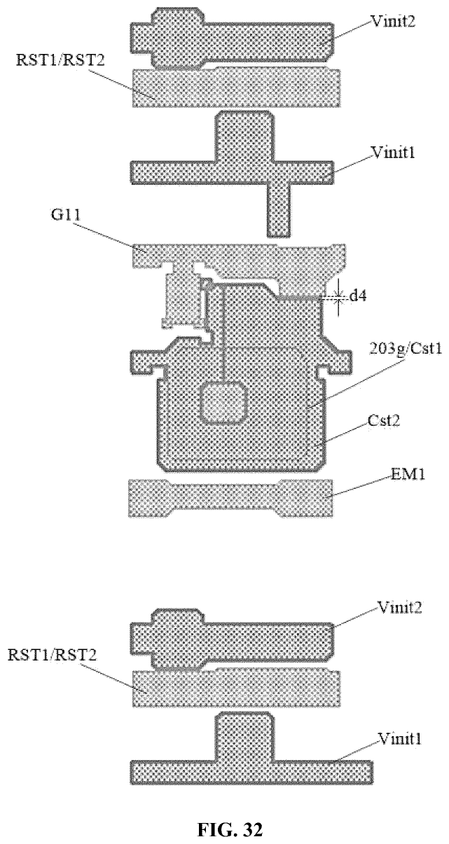

In at least part of the first target sub-pixel driving circuit layout area and/or at least part of the target virtual sub-pixel driving circuit layout area, along the first direction, there is a first distance d2 between the orthographic projection of the first target protrusion G102 on the base substrate 10 and the orthographic projection of the second electrode plate Cst2 on the base substrate 10; in the first non-target sub-pixel driving circuit layout area and/or the non-target virtual sub-pixel driving circuit layout area, along the first direction, there is a second distance d4 between the orthographic projection of the first non-target protrusion G111 on the base substrate 10 and the orthographic projection of the second electrode plate Cst2 on the base substrate 10 (see FIG. 32); the first distance d2 is greater than the second distance d4.

Exemplarily, in at least part of the first target sub-pixel driving circuit layout area and/or at least part of the target virtual sub-pixel driving circuit layout area, the first distance can be made greater than the second distance by reducing the area of the second electrode plate Cst2 and/or changing the layout structure of the second electrode plate Cst2.

The above-mentioned setting of the first distance being greater than the second distance reduces the coupling capacitance formed by the first target scanning line G10, so that the coupling capacitance formed by the first target scanning line G10 is substantially the same as the coupling capacitance formed by the first non-target scanning line G11, thereby avoiding the difference in charging time caused by the difference between the coupling capacitance formed by the first target scanning line G10 and the coupling capacitance formed by the first non-target scanning line G11, and ensuring the brightness uniformity of the display substrate.

As shown in FIG. 1, FIG. 2, FIG. 20 to FIG. 25, and FIG. 42, in some embodiments, at least part of the first non-target sub-pixel driving circuit 211 and/or at least part of the non-target virtual sub-pixel driving circuit 212 includes:
a driving transistor and a compensating transistor (i.e., a second transistor T2), wherein a first electrode of the compensating transistor is coupled to a second electrode of the driving transistor, and the second electrode of the compensating transistor is coupled to a gate 203g of the driving transistor via a first conductive connecting portion 61;
the third compensation pattern 43 is coupled to the first conductive connection portion 61, and the orthographic projection of the third compensation pattern 43 on the base substrate 10 has a third overlapping area with the orthographic projection of the first non-target scanning line G11 on the base substrate 10.

Exemplarily, the third compensation pattern 43 and the first conductive connection portion 61 are formed into an integral structure.

The above configuration increases the capacitance between at least part of the first non-target scanning line G11 and the first conductive connection portion 61, which is equivalent to increasing the capacitance between at least part of the first non-target scanning line G11 and the N1 node, that is, increasing the coupling capacitance of at least part of the first non-target scanning line G11.

The above-mentioned setting includes at least part of the first non-target sub-pixel driving circuit 211 and/or at least part of the non-target virtual sub-pixel driving circuit 212 including the third compensation pattern 43, which increases the coupling capacitance formed by the first non-target scanning line G11, so that the coupling capacitance formed by the first target scanning line G10 is substantially the same as the coupling capacitance formed by the first non-target scanning line G11, thereby avoiding the difference in charging time caused by the difference between the coupling capacitance formed by the first target scanning line G10 and the coupling capacitance formed by the first non-target scanning line G11, and ensuring the brightness uniformity of the display substrate.

Exemplarily, in a row of target drive circuits 20, the coupling capacitance formed between the conductive connection line 30 and the first target scanning line G10 is between 560 fF and 750 fF. In a sub-pixel drive circuit layout area (i.e., in a dot), the capacitance value of 2 fF can be increased or decreased through the solution provided by the above embodiment. Therefore, the difference in coupling capacitance can be compensated by changing the capacitance of 280 to 375 dots. The number of sub-pixel drive circuits included in each row of target drive circuits 20 and each row of non-target drive circuits 21 is sufficient to meet the compensation of coupling capacitance.

In some embodiments, in at least two non-target driving circuit rows 21 closest to the second display area 102, the third overlapping area gradually increases along the first direction and along the direction away from the first display area 101.

Exemplarily, in the other non-target driving circuit rows 21 except the at least two non-target driving circuit rows 21, the coupling capacitance formed by the first non-target scanning line G11 is substantially the same as the coupling capacitance formed by the first target scanning line G10.

The third overlapping area is set to gradually increase, so that in at least two rows of non-target driving circuit rows 21 closest to the second display area 102, along the first direction and in the direction away from the first display area 101, the coupling capacitance formed by the first non-target scanning line G11 gradually increases until it reaches or approaches the coupling capacitance formed by the first target scanning line G10.

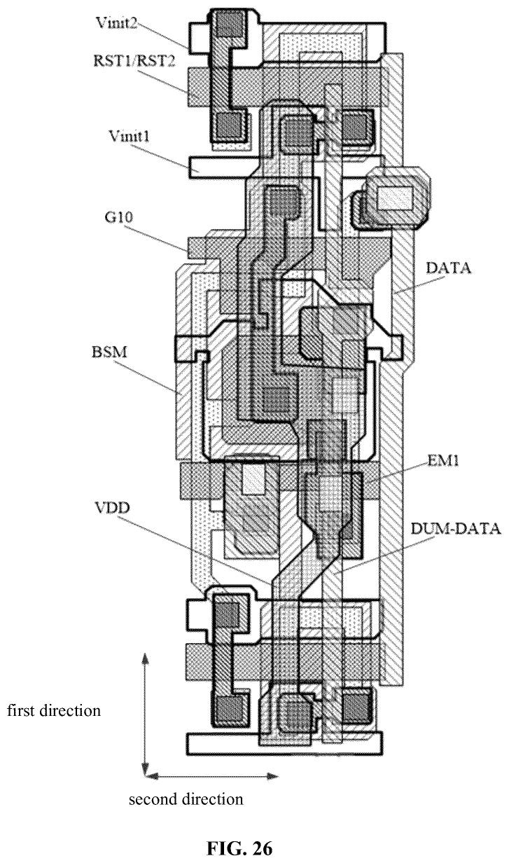

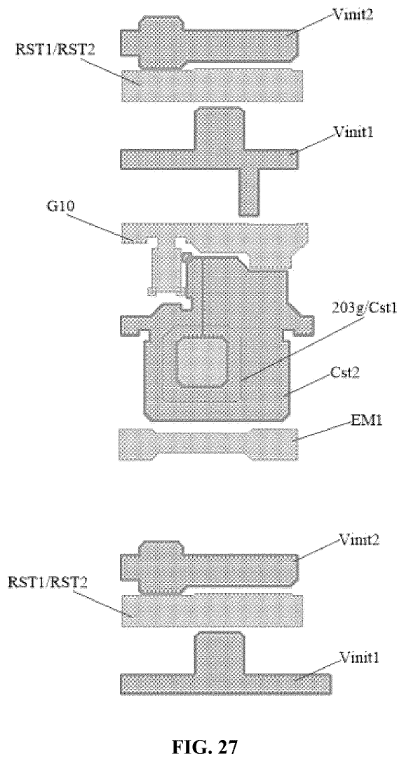

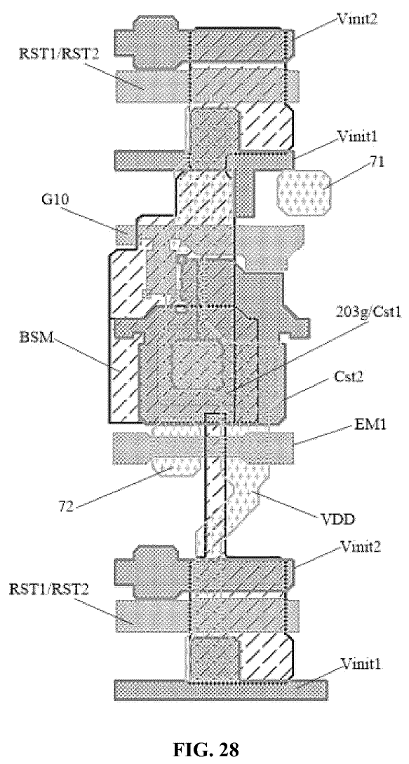

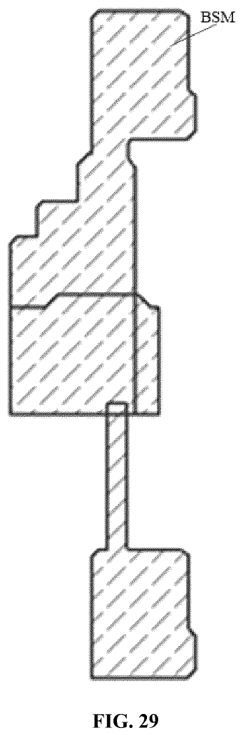

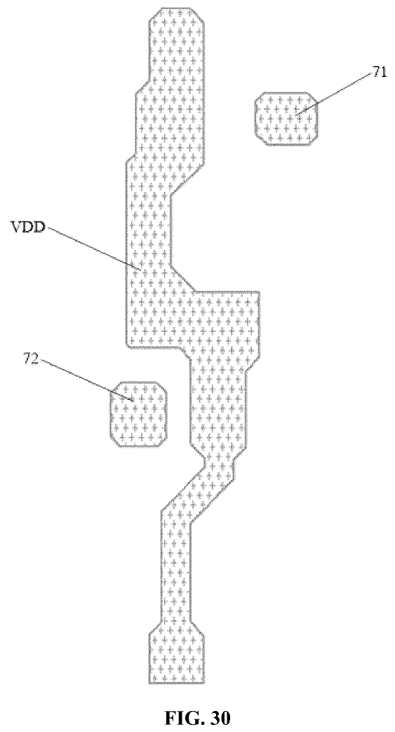

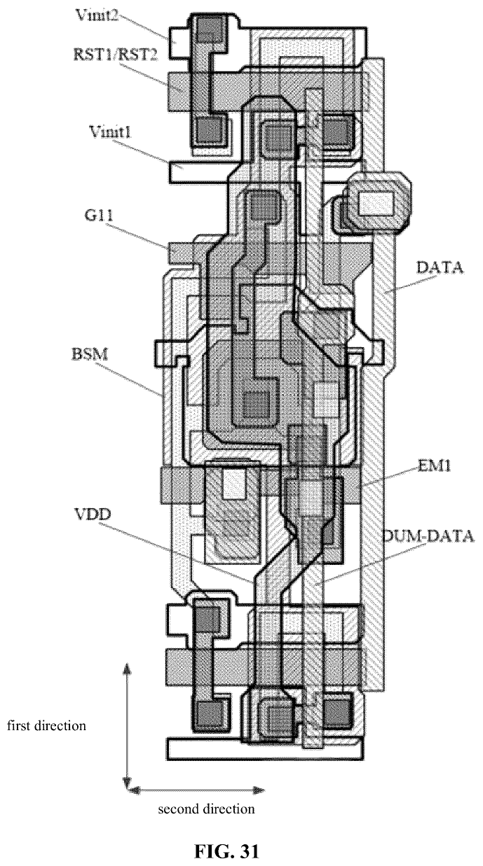

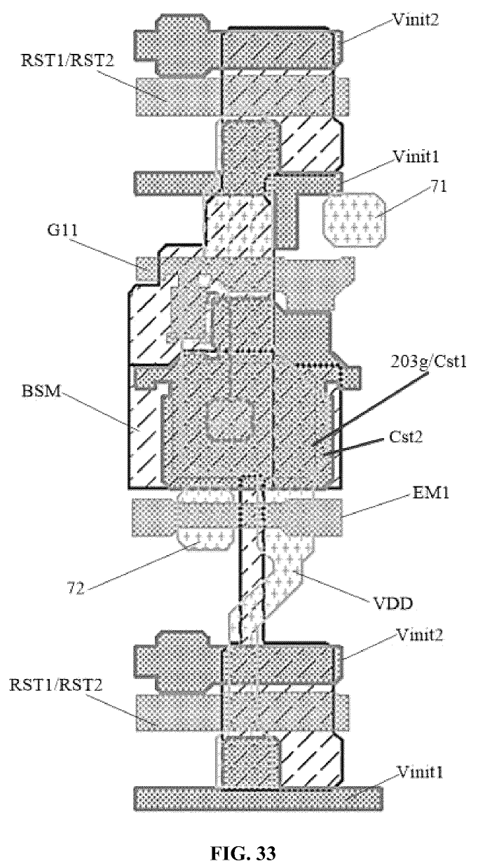

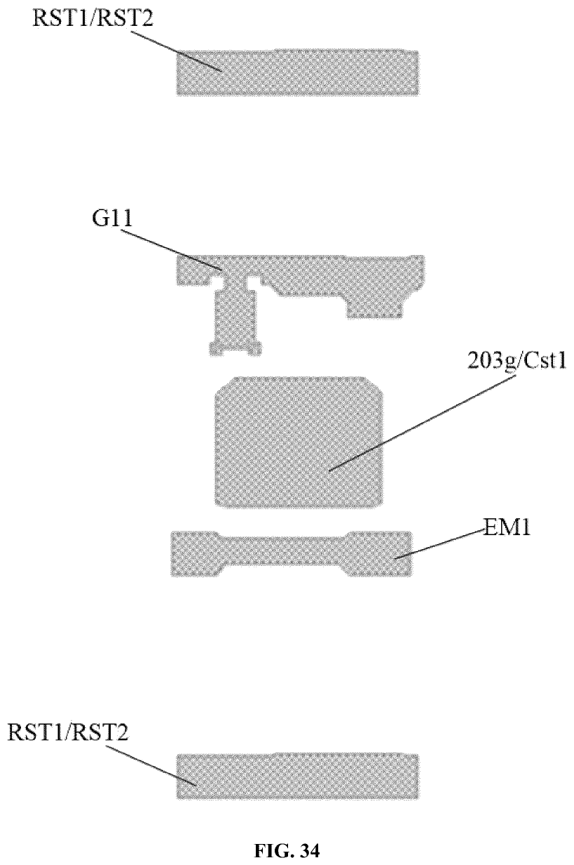

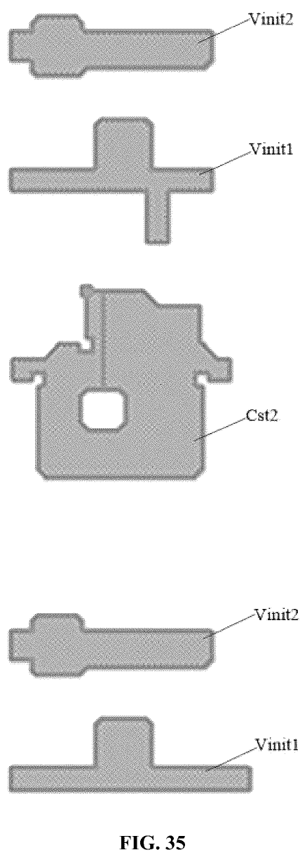

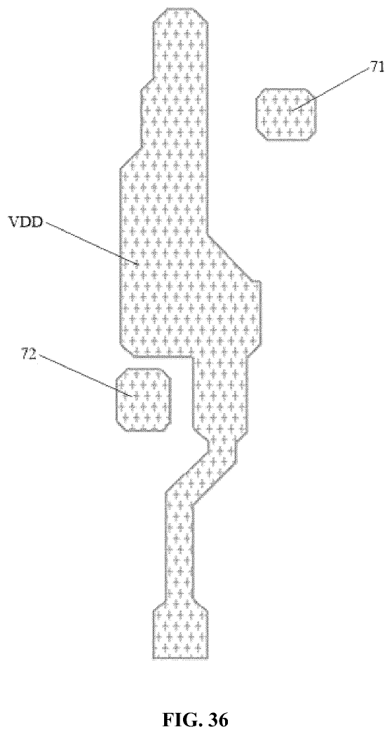

As shown in FIG. 1, FIG. 2, FIG. 26 to FIG. 30, and FIG. 31 to FIG. 36, in some embodiments, the display substrate includes a power line VDD; the first target sub-pixel driving circuit 201, the target virtual sub-pixel driving circuit 202 and the first non-target sub-pixel driving circuit 211 each include: a storage capacitor Cst and a driving transistor, the first plate Cst1 of the storage capacitor Cst is coupled to the gate 203g of the driving transistor, and the second plate Cst2 of the storage capacitor Cst is coupled to the corresponding power line VDD;
a capacitance value of a storage capacitor in at least part of the first target sub-pixel driving circuit 201 and/or at least part of the target virtual sub-pixel driving circuit 202 is smaller than a capacitance value of a storage capacitor Cst in at least part of the first non-target sub-pixel driving circuit 211.

Exemplarily, the capacitance value of the storage capacitor Cst in at least part of the first target sub-pixel driving circuit 201 and/or at least part of the target virtual sub-pixel driving circuit 202 is smaller than the capacitance value of the storage capacitor Cst in the first non-target sub-pixel driving circuit 211.

Exemplarily, the capacitance value of the storage capacitor Cst in the first target sub-pixel driving circuit 201 and/or the target virtual sub-pixel driving circuit 202 is smaller than the capacitance value of the storage capacitor Cst in at least part of the first non-target sub-pixel driving circuit 211.

Exemplarily, the capacitance value of the storage capacitor Cst in at least a portion of the first target sub-pixel driving circuit 201 and/or at least a portion of the target virtual sub-pixel driving circuit 202 is reduced to increase the voltage of the N1 node.

Exemplarily, the capacitance of the storage capacitor Cst in at least part of the first non-target sub-pixel driving circuit 211 is increased to reduce the voltage of the N1 node.

The above configuration can achieve that the voltage of the N1 node corresponding to the target drive circuit row 20 is substantially the same as the voltage of the N1 node corresponding to the non-target drive circuit row 21, which can effectively improve the horizontal stripe Mura of the row where the second display area 102 is located, and ensure the brightness uniformity of the display substrate.

As shown in FIGS. 1, 2, 26 to 30, and 31 to 36, in some embodiments, the area of the first plate Cst1 in at least part of the first target sub-pixel driving circuit 201 and/or at least part of the target virtual sub-pixel driving circuit 202 is smaller than the area of the first plate Cst1 in at least part of the first non-target sub-pixel driving circuit 211.

As shown in FIG. 1, FIG. 2, FIG. 26 to FIG. 30, and FIG. 31 to FIG. 36, in some embodiments, the area of the second electrode plate Cst2 in at least part of the first target sub-pixel driving circuit 201 and/or at least part of the target virtual sub-pixel driving circuit 202 is smaller than the area of the second electrode plate Cst2 in at least part of the first non-target sub-pixel driving circuit 211. Exemplarily, the area of the second electrode plate Cst2 in at least part of the first non-target sub-pixel driving circuit 211 can be increased by reducing the size of the opening of the second electrode plate Cst2 in the first non-target sub-pixel driving circuit 211.

As shown in FIGS. 1, 2, 26 to 30, and 31 to 36, in some embodiments, the display substrate also includes a shading layer BSM; in at least part of the first target sub-pixel driving circuit 201 and/or at least part of the target virtual sub-pixel driving circuit 202, an orthographic projection of the first electrode plate Cst1 on the base substrate has a fourth overlapping area with an orthographic projection of the light-shielding layer on the base substrate 10; in at least part of the first non-target sub-pixel driving circuit 211, the orthographic projection of the first electrode plate Cst1 on the base substrate has a fifth overlapping area with an orthographic projection of the light-shielding layer on the base substrate 10; the fourth overlapping area is smaller than the fifth overlapping area.

As shown in FIGS. 1, 2, 26 to 30, and 31 to 36, in some embodiments, in at least part of the first target sub-pixel driving circuit 201 and/or at least part of the target virtual sub-pixel driving circuit 202, an orthographic projection of the second electrode plate Cst2 on the base substrate has a sixth overlapping area with the orthographic projection of the power line VDD on the base substrate 10; in at least part of the first non-target sub-pixel driving circuit 211, an orthographic projection of the second electrode plate Cst2 on the base substrate has a seventh overlapping area with the orthographic projection of the power line VDD on the base substrate 10; the sixth overlapping area is smaller than the seventh overlapping area.

The above-mentioned configuration can achieve that: the capacitance value of the storage capacitor Cst in at least part of the first target sub-pixel driving circuit 201 and/or at least part of the target virtual sub-pixel driving circuit 202 is smaller than the capacitance value of the storage capacitor Cst in at least part of the first non-target sub-pixel driving circuit 211.

In some embodiments, along the first direction and along the direction close to the first display area 101, the capacitance value of the storage capacitor Cst in the target driving circuit row 20 gradually increases.

In some embodiments, in at least two non-target driving circuit rows 21 closest to the second display area, along the first direction and along the direction close to the second display area 102, the capacitance value of the storage capacitor Cst gradually increases.

Exemplarily, among the at least two non-target driving circuit rows 21, the storage capacitor Cst in the non-target driving circuit row 21 closest to the second display area 102 has a capacitance equal to or close to that of the storage capacitor Cst in the target driving circuit row 20.

The above setting of the capacitance value of the storage capacitor Cst gradually increases, which effectively improves the horizontal stripe Mura of the row where the second display area 102 is located, and ensures the brightness uniformity of the display substrate.

In some embodiments, the display substrate further includes a compensation planarization layer, and at least a portion of the compensation planarization layer is located between the conductive connection line 30 and the first target scanning line G10.

The coupling capacitance between the conductive connection line 30 and the first target scanning line G10 by increasing the thickness of the compensation planarization layer, thereby reducing the loading of the first target scanning line G10.

As shown in FIG. 42, in some embodiments, the display substrate includes a light shielding layer BSM, an active layer poly, a first gate insulating layer GI1, a first gate metal layer gate1, a second gate insulating layer GI2, a second gate metal layer gate2, an interlayer insulating layer ILD, a first source-drain metal layer SD1, a first flat layer PLN1, a compensation source-drain metal layer SDM, a second flat layer PLN2, a second source-drain metal layer SD2, a third flat layer PLN3, an anode layer ANO, a pixel defining layer PDL, a light emitting function layer EL0, a cathode layer cath, a first inorganic encapsulation layer CVD1, an organic encapsulation layer IJP, and a second inorganic encapsulation layer CVD2, which are sequentially stacked in a direction away from the base substrate 10. The display substrate may also include a passivation layer PVX, but is not limited to it.

Exemplarily, the conductive connection line 30 can be provided in the same layer and material as the anode layer ANO, or a special patterning process can be added to form the conductive connection line 30. The conductive connection line 30 is located on the side of the second source-drain metal layer SD2 facing away from the base substrate.

The compensation planarization layer may be disposed at any layer between the first source-drain metal layer SD1 and the conductive connection line 30.

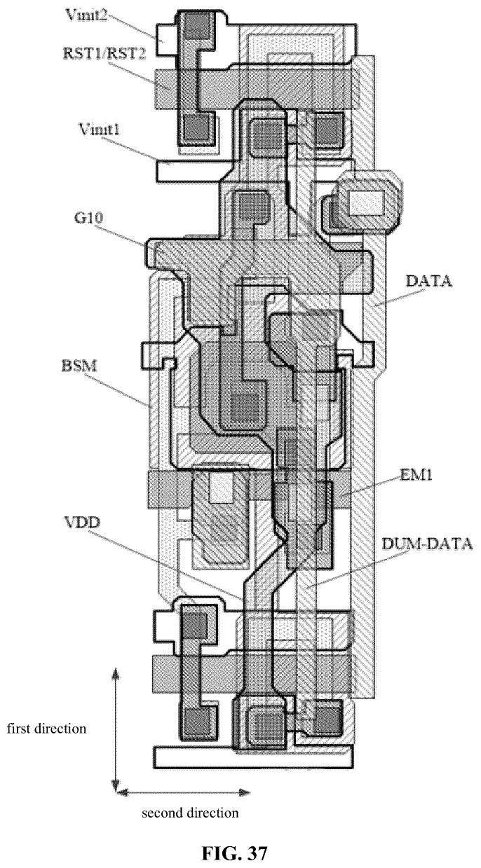

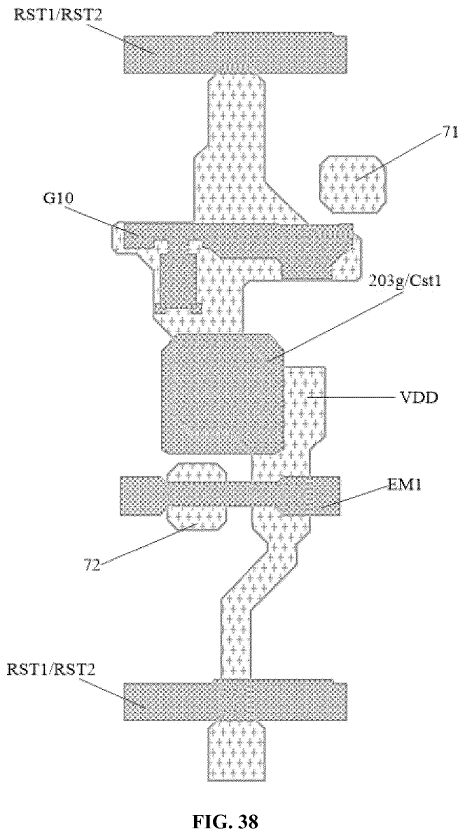

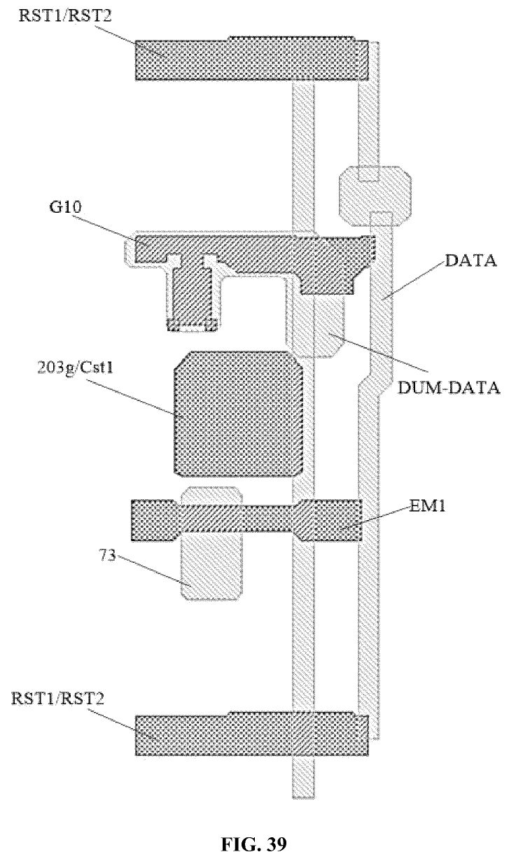

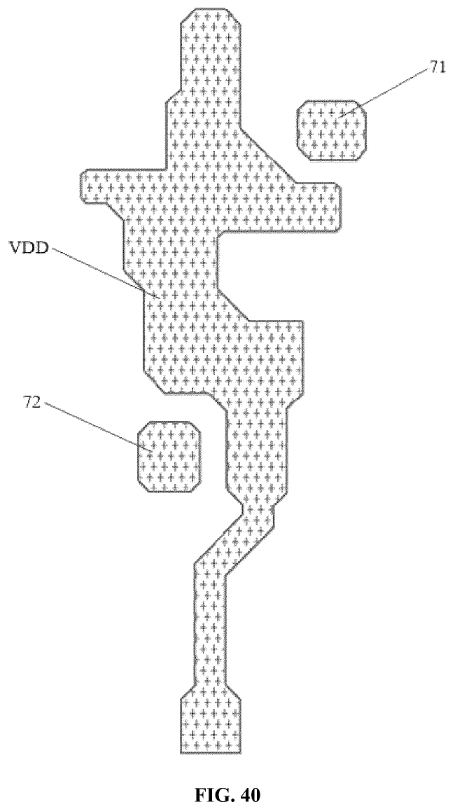

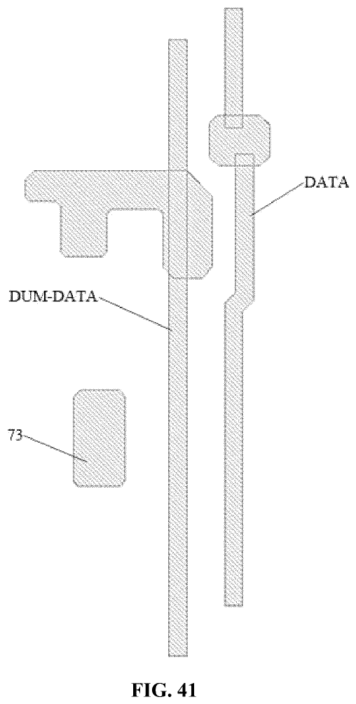

As shown in FIGS. 37 to 42, in some embodiments, the display substrate also includes a power line VDD; in at least part of the first target sub-pixel driving circuit layout area and/or at least part of the target virtual sub-pixel driving circuit layout area, the power line VDD has an eighth overlapping area between the orthographic projection of the power line VDD on the base substrate 10 and the orthographic projection of the first target scanning line G10 on the base substrate 10, and the eighth overlapping area is greater than 80% of the area of the first target scanning line G10 in the first target sub-pixel driving circuit layout area, or the eighth overlapping area is greater than 80% of the area of the first target scanning line G10 in the target virtual sub-pixel driving circuit layout area.

Exemplarily, by adjusting the area and layout structure of the power line VDD, the eighth overlapping area can be larger than 80% of the area of the first target scanning line G10 in the first target sub-pixel driving circuit layout area, or the eighth overlapping area can be larger than 80% of the area of the first target scanning line G10 in the target virtual sub-pixel driving circuit layout area.

Exemplarily, the eighth overlapping area is equal to 80%, 85%, 90%, 95% or 100% of the area of the first target scanning line G10 in the first target sub-pixel driving circuit layout area.

Exemplarily, the eighth overlapping area is equal to 80%, 85%, 90%, 95% or 100% of the area of the first target scanning line G10 in the target virtual sub-pixel driving circuit layout area.

Exemplarily, in at least part of the first target sub-pixel driving circuit layout area and/or at least part of the target virtual sub-pixel driving circuit layout area, the orthographic projection of the power line VDD on the base substrate 10 completely covers the orthographic projection of the first target scanning line G10 on the base substrate 10.

The above configuration enables the power line VDD to separate the first target scanning line G10 and the conductive connecting line 30, thereby reducing the coupling capacitance between the first target scanning line G10 and the conductive connecting line 30.

In some embodiments, the display substrate also includes a virtual data line DUM-DATA; in at least part of the first target sub-pixel drive circuit layout area and/or at least part of the target virtual sub-pixel drive circuit layout area, the virtual data line DUM-DATA has a ninth overlapping area between the orthographic projection of the first target scanning line G10 on the base substrate 10 and the orthographic projection of the first target scanning line G10 on the base substrate 10, and the ninth overlapping area is greater than 80% of the area of the first target scanning line G10 in the first target sub-pixel drive circuit layout area, or the ninth overlapping area is greater than 80% of the area of the first target scanning line G10 in the target virtual sub-pixel drive circuit layout area.

Exemplarily, the area and layout structure of the virtual data line DUM-DATA can be adjusted to achieve the ninth overlapping area being larger than 80% of the area of the first target scanning line G10 in the first target sub-pixel driving circuit layout area, or the ninth overlapping area being larger than 80% of the area of the first target scanning line G10 in the target virtual sub-pixel driving circuit layout area.

Exemplarily, the ninth overlapping area is equal to 80%, 85%, 90%, 95% or 100% of the area of the first target scanning line G10 in the first target sub-pixel driving circuit layout area.

Exemplarily, the ninth overlapping area is equal to 80%, 85%, 90%, 95% or 100% of the area of the first target scanning line G10 in the target virtual sub-pixel driving circuit layout area.

Exemplarily, in at least part of the first target sub-pixel driving circuit layout area and/or at least part of the target virtual sub-pixel driving circuit layout area, the orthographic projection of the virtual data line DUM-DATA on the base substrate 10 completely covers the orthographic projection of the first target scanning line G10 on the base substrate 10.

The above configuration enables the virtual data line DUM-DATA to separate the first target scanning line G10 and the conductive connection line 30, thereby reducing the coupling capacitance between the first target scanning line G10 and the conductive connection line 30.

As shown in FIG. 1, in some embodiments, the first target sub-pixel driving circuit 201, part of the target virtual sub-pixel driving circuit 202, and the first non-target sub-pixel driving circuit 211 may adopt a circuit structure of 7T1C (including 7 transistors and 1 and a storage capacitor Cst), but is not limited thereto.

The 7T1C circuit structure includes: a first transistor T1, a second transistor T2, a third transistor T3, a fourth transistor T4, a fifth transistor T5, a sixth transistor T6, a seventh transistor T7 and a storage capacitor Cst; the first transistor T1, the second transistor T2, the third transistor T3, the fourth transistor T4, the fifth transistor T5, the sixth transistor T6, and the seventh transistor T7 can all be P-type transistors.

The gate 201g of the first transistor T1 is coupled to the corresponding first reset signal line RST1, the source S1 of the first transistor T1 is coupled to the corresponding first initialization signal line Vinit1, and the drain D1 of the first transistor T1 is coupled to the gate 203g of the third transistor T3.

The gate 202g of the second transistor T2 is coupled to the corresponding first scanning line, the source S2 of the second transistor T2 is coupled to the drain D3 of the third transistor T3, and the drain D2 of the second transistor T2 is coupled to the gate 203g of the third transistor T3.

The gate 204g of the fourth transistor T4 is coupled to the corresponding first scanning line, the source S4 of the fourth transistor T4 is coupled to the corresponding data line DATA, and the drain D4 of the fourth transistor T4 is coupled to the source S3 of the third transistor T3.

The gate 205g of the fifth transistor T5 is coupled to the corresponding light emitting control signal line EM1, the source S5 of the fifth transistor T5 is coupled to the corresponding power line VDD, and the drain D5 of the fifth transistor T5 is coupled to the source S3 of the third transistor T3.

The gate 206g of the sixth transistor T6 is coupled to the corresponding light emitting control signal line EM1, the source S6 of the sixth transistor T6 is coupled to the drain D3 of the third transistor T3, and the drain D6 of the sixth transistor T6 is coupled to the anode of the light emitting element EL.

The gate 207g of the seventh transistor T7 is coupled to the second reset signal line RST2, the drain D7 of the seventh transistor T7 is coupled to the anode of the light emitting element EL, and the source S7 of the seventh transistor T7 is coupled to the corresponding second initialization signal line Vinit2.

The first plate Cst1 of the storage capacitor Cst is coupled to the gate 203g of the third transistor T3. Therefore, the gate 203g of the third transistor T3 can be directly reused as the first plate Cst1 of the storage capacitor Cst. The second plate Cst2 of the storage capacitor Cst is coupled to the corresponding power line VDD.

An embodiment of the present disclosure further provides a display device, comprising the display substrate provided by the above embodiment.

The display device includes a flexible organic light emitting diode display device, but is not limited thereto.

It should be noted that the display device can be any product or component with a display function, such as a television, a monitor, a digital photo frame, a mobile phone, a tablet computer, etc., wherein the display device also includes a flexible circuit board, a printed circuit board and a backplane, etc.

In the above embodiment, the orthographic projection of the conductive connection line 30 on the base substrate 10 overlaps at least partially with the orthographic projection of the first target scanning line G10 on the base substrate 10, which will affect the charging time of the sub-pixel driving circuit. By setting the charging time of the target driving circuit row 20 to be substantially the same as the charging time of the non-target driving circuit row 21, the horizontal stripe Mura of the row where the second display area 102 is located can be effectively improved, thereby ensuring the brightness uniformity of the display substrate. The display device provided in the embodiment of the present disclosure also has the above-mentioned beneficial effects when including the above-mentioned display substrate, which will not be repeated here.

It should be noted that the signal line extends along the X direction means that the signal line includes a main part and a secondary part connected to the main part, the main part is a line, a line segment or a strip-shaped body, the main part extends along the X direction, and the length of the main part extending along the X direction is greater than the length of the secondary part extending along other directions.

It should be noted that the “same layer” in the embodiment of the present disclosure may refer to a film layer on the same structural layer. Or, for example, a film layer on the same layer may be a film layer for forming a specific pattern formed by the same film forming process, and then the film layer is patterned by the same mask through a single composition process to form a layer structure. Depending on the specific pattern, a single composition process may include multiple exposure, development or etching processes, and the specific pattern in the formed layer structure may be continuous or discontinuous. These specific patterns may also be at different heights or have different thicknesses.

In the various method embodiments of the present disclosure, the serial numbers of the steps cannot be used to limit the sequence of the steps. For ordinary technicians in this field, without paying any creative work, changes to the sequence of the steps are also within the protection scope of the present disclosure.

It should be noted that each embodiment in this specification is described in a progressive manner, and the same or similar parts between the embodiments can be referred to each other, and each embodiment focuses on the differences from other embodiments. In particular, for the method embodiment, since it is basically similar to the product embodiment, the description is relatively simple, and the relevant parts can be referred to the partial description of the product embodiment.

Unless otherwise defined, the technical terms or scientific terms used in the present disclosure should be understood by people with ordinary skills in the field to which the present disclosure belongs. The “first”, “second” and similar words used in the present disclosure do not indicate any order, quantity or importance, but are only used to distinguish different components. “Include” or “comprise” and similar words mean that the elements or objects appearing before the word cover the elements or objects listed after the word and their equivalents, without excluding other elements or objects. “Connect”, “couple” or “connected” and similar words are not limited to physical or mechanical connections, but can include electrical connections, whether direct or indirect. “Up”, “down”, “left”, “right” and the like are only used to indicate relative positional relationships. When the absolute position of the described object changes, the relative positional relationship may also change accordingly.

It will be understood that when an element such as a layer, film, region, or substrate is referred to as being “on” or “under” another element, it can be “directly on” or “under” the other element or intervening elements may be present.

In the description of the above embodiments, specific features, structures, materials or characteristics may be combined in a suitable manner in any one or more embodiments or examples.

The above is only a specific embodiment of the present disclosure, but the protection scope of the present disclosure is not limited thereto. Any person skilled in the art who is familiar with the technical field can easily think of changes or substitutions within the technical scope disclosed in the present disclosure, which should be included in the protection scope of the present disclosure. Therefore, the protection scope of the present disclosure should be based on the protection scope of the claims.

1. A display substrate, comprising a base substrate, the base substrate comprising a first display area and a second display area, the first display area being at least located on one side of the second display area; the display substrate further comprising: a plurality of first sub-pixels, a plurality of second sub-pixels and a plurality of virtual sub-pixel driving circuits; the first sub-pixels and the virtual sub-pixel driving circuits being located in the first display area, the first sub-pixels comprising a first sub-pixel driving circuit and a first light-emitting element coupled to each other; the second sub-pixel comprising a second light-emitting element located in the second display area; the plurality of virtual sub-pixel driving circuits comprising a plurality of target virtual sub-pixel driving circuits and a plurality of non-target virtual sub-pixel driving circuits, and part of the target virtual sub-pixel driving circuits being coupled to corresponding second light-emitting elements through conductive connecting lines;
the plurality of first sub-pixel driving circuits included in the plurality of first sub-pixels are divided into a plurality of first target sub-pixel driving circuits and a plurality of first non-target sub-pixel driving circuits; the plurality of target virtual sub-pixel driving circuits are divided into a plurality of target driving circuit rows together with the plurality of first target sub-pixel driving circuits, each of the target driving circuit rows comprises a first target sub-pixel driving circuit and a target virtual sub-pixel driving circuit; the plurality of first non-target sub-pixel driving circuits and the plurality of non-target virtual sub-pixel driving circuits are divided into a plurality of non-target driving circuit rows, each of the non-target driving circuit rows comprises a first non-target sub-pixel driving circuit and a non-target virtual sub-pixel driving circuit;
the display substrate further comprises a plurality of first target scanning lines and a plurality of first non-target scanning lines, wherein the first target scanning lines are respectively coupled to each of the target virtual sub-pixel drive circuits and each of the first target sub-pixel drive circuits in the corresponding target drive circuit row; and the first non-target scanning lines are respectively coupled to each of the non-target virtual sub-pixel drive circuits and each of the first non-target sub-pixel drive circuits in the corresponding non-target drive circuit row;
an orthographic projection of the conductive connection line on the base substrate at least partially overlaps with an orthographic projection of the first target scanning line on the base substrate;
gates of the driving transistors in at least part of the sub-pixel driving circuits included in the target driving circuit row are configured to have substantially the same potential as the gates of the driving transistors in at least part of the sub-pixel driving circuits included in the non-target driving circuit row after charging.

2. The display substrate according to claim 1, wherein the display substrate comprises a data line and a power line;
at least part of the first target sub-pixel driving circuit and/or at least part of the target virtual sub-pixel driving circuit comprises:
a driving transistor and a data writing transistor, wherein a first electrode of the data writing transistor is coupled to the corresponding data line, and a second electrode of the data writing transistor is coupled to the first electrode of the driving transistor;
a first compensation pattern and a second compensation pattern, wherein the first compensation pattern is coupled to the first electrode of the driving transistor, the second compensation pattern is coupled to the corresponding power line, and the orthographic projection of the first compensation pattern on the base substrate at least partially overlaps with the orthographic projection of the second compensation pattern on the base substrate.

3. The display substrate according to claim 2, wherein the data writing transistor comprises a fourth active layer, the fourth active layer comprises an active body portion and an active protrusion portion, the active body portion extends along a first direction, and the active protrusion portion protrudes from the active body portion along a second direction; the first direction intersects the second direction;
the first compensation pattern is coupled to the active protrusion, and the first compensation pattern is located on a side of the active protrusion away from the base substrate.

4. The display substrate according to claim 3, wherein the display substrate comprises a light shielding layer, an active layer, a first gate metal layer, a second gate metal layer, a first source-drain metal layer, a compensation source-drain metal layer and a second source-drain metal layer which are sequentially stacked in a direction away from the base substrate, and the first compensation pattern is arranged in the same layer and material as the first source-drain metal layer.

5. The display substrate according to claim 3, wherein the second compensation pattern and the power line coupled thereto are formed as an integral structure.

6. The display substrate according to claim 3, wherein at least part of the first target sub-pixel driving circuit and/or at least part of the target virtual sub-pixel driving circuit further comprises: a storage capacitor, the storage capacitor comprising a first electrode plate and a second electrode plate arranged opposite to each other, the first electrode plate is located between the base substrate and the second electrode plate;
an orthographic projection of the second electrode plate on the base substrate partially overlaps with an orthographic projection of the active protrusion on the base substrate; or, the orthographic projection of the second electrode plate on the base substrate does not overlap with the orthographic projection of the active protrusion on the base substrate.

7. The display substrate according to claim 3, wherein an orthographic projection of the second electrode plate on the base substrate at least partially overlaps with an orthographic projection of the first compensation pattern on the base substrate.

8. The display substrate according to claim 1, wherein a difference A between a coupling capacitance formed by the first target scanning line and a coupling capacitance formed by the first non-target scanning line satisfies: A≤80 fF.

9. The display substrate according to claim 8, wherein A≤60 fF; or A≤30 fF.

10. The display substrate according to claim 8, wherein the display substrate further comprises a light shielding layer; an orthographic projection of the first target scanning line on the base substrate and an orthographic projection of the light shielding layer on the base substrate have a first overlapping area; an orthographic projection of the first non-target scanning line on the base substrate and the orthographic projection of the light shielding layer on the base substrate have a second overlapping area; the first overlapping area is smaller than the second overlapping area.

11. The display substrate according to claim 8, wherein, in at least one first target sub-pixel driving circuit layout area and/or in at least one target virtual sub-pixel driving circuit layout area, the area of the first target scanning line is smaller than the area of the first non-target scanning line in a first non-target sub-pixel driving circuit layout area and/or a non-target virtual sub-pixel driving circuit layout area.

12. The display substrate according to claim 11, wherein at least part of the first target sub-pixel driving circuit, at least part of the target dummy sub-pixel driving circuit, and the first non-target sub-pixel driving circuit and the non-target dummy sub-pixel driving circuit all comprise a data writing transistor, and the data writing transistor comprises a fourth active layer;
the first target scanning line comprise a first target main body portion and a first target protrusion portion, the first target main body portion includes at least a portion extending along a second direction, the first target protrusion portion protrudes from the first target main body portion along a first direction, and the first direction intersects the second direction;
the first non-target scanning line comprise a first non-target main body portion and a first non-target protrusion portion, the first non-target main body portion includes at least a portion extending along the second direction, and the first non-target protrusion portion protrudes from the first non-target main body portion along the first direction;
an orthographic projection of the first target protrusion on the base substrate at least partially overlaps with an orthographic projection of the fourth active layer in the sub-pixel driving circuit layout area to which it belongs on the base substrate; the orthographic projection of the first non-target protrusion on the base substrate at least partially overlaps with the orthographic projection of the fourth active layer in the sub-pixel driving circuit layout area to which it belongs on the base substrate;
an area of the first target protrusion is smaller than an area of the first non-target protrusion.

13. The display substrate according to claim 12, wherein a width of the first target protrusion along the second direction is smaller than a width of the first non-target protrusion.

14. The display substrate according to claim 12, wherein the first target sub-pixel driving circuit, the target dummy sub-pixel driving circuit, the first non-target sub-pixel driving circuit, and the non-target dummy sub-pixel driving circuit all comprise: a storage capacitor, the storage capacitor comprising a first electrode plate and a second electrode plate arranged opposite to each other, the first electrode plate being located between the base substrate and the second electrode plate;
in at least part of the first target sub-pixel driving circuit layout area and/or at least part of the target virtual sub-pixel driving circuit layout area, along the first direction, there is a first distance between the orthographic projection of the first target protrusion on the base substrate and the orthographic projection of the second electrode plate on the base substrate; in the first non-target sub-pixel driving circuit layout area and/or the non-target virtual sub-pixel driving circuit layout area, along the first direction, there is a second distance between the orthographic projection of the first non-target protrusion on the base substrate and the orthographic projection of the second electrode plate on the base substrate; the first distance is greater than the second distance.

15. The display substrate according to claim 8, wherein at least part of the first non-target sub-pixel driving circuit and/or at least part of the non-target dummy sub-pixel driving circuit comprises:
a driving transistor and a compensating transistor, wherein a first electrode of the compensating transistor is coupled to a second electrode of the driving transistor, and the second electrode of the compensating transistor is coupled to a gate of the driving transistor via a first conductive connecting portion;
a third compensation pattern is coupled to the first conductive connection portion, and an orthographic projection of the third compensation pattern on the base substrate has a third overlapping area with an orthographic projection of the first non-target scanning line on the base substrate.

16. The display substrate according to claim 15, wherein in at least two non-target driving circuit rows closest to the second display area, the third overlapping area gradually increases along the first direction and in a direction away from the first display area.

17. The display substrate according to claim 15, wherein the third compensation pattern and the first conductive connection portion are formed as an integral structure.

18. The display substrate according to claim 2, wherein the display substrate comprises a power line; the first target sub-pixel driving circuit, the target virtual sub-pixel driving circuit and the first non-target sub-pixel driving circuit each comprise: a storage capacitor and a driving transistor, a first plate of the storage capacitor is coupled to a gate of the driving transistor, and a second plate of the storage capacitor is coupled to a corresponding power line;
a capacitance value of a storage capacitor in at least part of the first target sub-pixel driving circuit and/or at least part of the target virtual sub-pixel driving circuit is smaller than a capacitance value of a storage capacitor in at least part of the first non-target sub-pixel driving circuit;
wherein an area of the first electrode plate in at least part of the first target sub-pixel driving circuit and/or at least part of the target virtual sub-pixel driving circuit is smaller than an area of the first electrode plate in at least part of the first non-target sub-pixel driving circuit;
or
the display substrate further comprises a light-shielding layer; in at least part of the first target sub-pixel driving circuit and/or at least part of the target virtual sub-pixel driving circuit, an orthographic projection of the first electrode plate on the base substrate has a fourth overlapping area with an orthographic projection of the light-shielding layer on the base substrate; in at least part of the first non-target sub-pixel driving circuit, the orthographic projection of the first electrode plate on the base substrate has a fifth overlapping area with the orthographic projection of the light-shielding layer on the base substrate; the fourth overlapping area is smaller than the fifth overlapping area;
or
in at least part of the first target sub-pixel driving circuit and/or at least part of the target virtual sub-pixel driving circuit, an orthographic projection of the second electrode plate has a sixth overlapping area with an orthographic projection of the power line on the base substrate; in at least part of the first non-target sub-pixel driving circuit, the orthographic projection of the second electrode plate on the base substrate has a seventh overlapping area with the orthographic projection of the power line on the base substrate; the sixth overlapping area is smaller than the seventh overlapping area;
or
in at least two non-target driving circuit rows closest to the second display area, a capacitance value of the storage capacitor gradually increases along the first direction and along the direction close to the second display area.

19.-22. (canceled)

23. The display substrate according to claim 8, further comprising a compensation planarization layer, at least a portion of which is located between the conductive connection line and the first target scanning line;
the display substrate further comprises a power line; in at least part of the first target sub-pixel driving circuit layout area and/or at least part of the target virtual sub-pixel driving circuit layout area, an orthographic projection of the power line on the base substrate has an eighth overlapping area with an orthographic projection of the first target scanning line on the base substrate, and the eighth overlapping area is greater than 80% of the area of the first target scanning line in the first target sub-pixel driving circuit layout area, or the eighth overlapping area is greater than 80% of the area of the first target scanning line in the target virtual sub-pixel driving circuit layout area;
or
the display substrate further comprises a virtual data line; in at least part of the first target sub-pixel driving circuit layout area and/or at least part of the target virtual sub-pixel driving circuit layout area, an orthographic projection of the virtual data line on the base substrate has a ninth overlapping area with an orthographic projection of the first target scanning line on the base substrate, and the ninth overlapping area is greater than 80% of the area of the first target scanning line in the first target sub-pixel driving circuit layout area, or the ninth overlapping area is greater than 80% of the area of the first target scanning line in the target virtual sub-pixel driving circuit layout area.

24.-25. (canceled)

26. A display device comprising the display substrate according to claim 1.
